(19) United States
(12) Patent Application Publication
(10) Pub. No.: US 2025/0266332 A1
(43) Pub. Date: Aug. 21, 2025

(54) ELECTRONIC DEVICE

(71) Applicant: Rohm Co., Ltd., Kyoto-shi (JP)

(72) Inventors: Hiroaki MATSUBARA, Kyoto-shi (JP); Ryohei UMENO, Kyoto-shi (JP); Takahiro NEGORO, Kyoto-shi (JP)

(21) Appl. No.: 19/189,854

(22) Filed: Apr. 25, 2025

Related U.S. Application Data
(63) Continuation of application No. PCT/JP2023/037986, filed on Oct. 20, 2023.

(30) Foreign Application Priority Data
Nov. 1, 2022 (JP) 2022-175672

(51) Int. Cl. H01L 23/495; H01L 23/31

(52) U.S. Cl. CPC H01L 23/49548; H01L 23/3107

(57) ABSTRACT

An electronic device comprises an electronic component, a sealing resin and a lead. The sealing resin includes a surface facing a first direction and covering the electronic component. The lead includes a root portion extending from the surface in the first direction, a mounting portion offset on the thickness direction with respect to the root portion, and an extending portion connected to the root portion through a first bent portion and to the mounting portion through a second bent portion. The lead includes a first section including the root portion, and a second section including the mounting portion. A width of the first section is greater than a width of the second section. A first section boundary between the first section and the second section is located between a boundary, which is between the root portion and the first bent portion, and a center of the extending portion.

### TECHNICAL FIELD

The present disclosure relates to an electronic device.

BACKGROUND ART

Conventionally, a semiconductor device that is manufactured using a lead frame has been known as an example of various kinds of electronic devices. One example of such a semiconductor device is described in JP-A-2022-55599, for example. The conventional semiconductor device disclosed in the document includes a semiconductor element, a conductive support, and a sealing resin. The conductive support includes a die pad and a plurality of terminals (input-side terminals, high-voltage output-side terminals, and low-voltage output-side terminals). The semiconductor device is of an SOP (Small Outline Package) package type. In the SOP package type, the plurality of terminals are bent in a gull-wing shape. The semiconductor device is mounted on a circuit board in a vehicle, electrical equipment, or the like.

### BRIEF DESCRIPTION OF THE DRAWINGS

FIG. 1 is a plan view of an electronic device according to a first embodiment.

FIG. 2 is a plan view, in which the sealing resin shown in FIG. 1 is indicated by imaginary lines.

FIG. 3 is a front view of the electronic device according to the first embodiment.

FIG. 4 is a bottom view of the electronic device according to the first embodiment.

FIG. 5 is a left-side view of the electronic device according to the first embodiment.

FIG. 6 is a right-side view of the electronic device according to the first embodiment.

FIG. 7 is a cross-sectional view taken along a line VII-VII of FIG. 2.

FIG. 8 is a cross-sectional view taken along a line VIII-VIII of FIG. 2.

FIG. 9 is an enlarged view illustrating a relevant part of the electronic device according to the first embodiment, wherein the upper portion is an enlargement of a part of FIG. 1 and lower portion is an enlargement of a part of FIG. 5.

FIG. 10 is an enlarged view illustrating a relevant part of the electronic device according to the first embodiment, wherein the upper portion is an enlargement of a part of FIG. 1 and the lower portion is an enlargement of a part of FIG. 6.

FIG. 11 is the schematic diagram of the electronic components of the electronic device according to the first embodiment.

FIG. 12 is an enlarged plan view illustrating a relevant part of the electronic device according to the first embodiment during its manufacturing process.

FIG. 13 is a plan view of an electronic device according to a variation of the first embodiment, with the sealing resin indicated by imaginary lines.

FIG. 14 is an enlarged view illustrating a relevant part of the electronic device according to the variation of the first embodiment, wherein the upper portion is an enlarged plan view of the relevant part and the lower portion is an enlarged side view of the relevant part.

FIG. 15 is an enlarged view illustrating a relevant part of the electronic device according to the variation of the first embodiment, wherein the upper portion is an enlarged plan view of the relevant part and the lower portion is an enlarged side view of the relevant part.

FIG. 16 is an enlarged view illustrating a relevant part of an electronic device according to another variation of the first embodiment, wherein the upper portion is an enlarged plan view of the relevant part and the lower portion is an enlarged side view of the relevant part.

FIG. 17 is an enlarged view illustrating a relevant part of an electronic device according to another variation of the first embodiment, wherein the upper portion is an enlarged plan view of the relevant part and the lower portion is an enlarged side view of the relevant part.

FIG. 18 is an enlarged plan view illustrating a relevant part of an electronic device according to another variation of the first embodiment.

FIG. 19 is an enlarged plan view illustrating a relevant part of an electronic device according to another variation of the first embodiment.

FIG. 20 is an enlarged plan view illustrating a relevant part of an electronic device according to another variation of the first embodiment.

FIG. 21 is a plan view of an electronic device according to a second embodiment, with the sealing resin indicated by imaginary lines.

FIG. 22 is a back view of the electronic device according to the second embodiment.

FIG. 23 is an enlarged view illustrating a relevant part of the electronic device according to the second embodiment, wherein the upper portion is an enlarged plan view of the relevant part and the lower portion is an enlarged side view of the relevant part.

FIG. 24 is an enlarged view illustrating a relevant part of the electronic device according to the second embodiment, wherein the upper portion is an enlarged plan view of the relevant part and the lower portion is an enlarged side view of the relevant part.

FIG. 25 is a plan view of an electronic device according to a variation of the second embodiment, with the sealing resin indicated by imaginary lines.

FIG. 26 is an enlarged view illustrating a relevant part of the electronic device according to the variation of the second embodiment, wherein the upper portion is an enlarged plan view of the relevant part and the lower portion is an enlarged side view of the relevant part.

FIG. 27 is an enlarged view illustrating a relevant part of the electronic device according to the variation of the second embodiment, wherein the upper portion is an enlarged plan view of the relevant part and the lower portion is an enlarged side view of the relevant part.

FIG. 28 is an enlarged view illustrating a relevant part of an electronic device according to another variation of the second embodiment, wherein the upper portion is an enlarged plan view of the relevant part and the lower portion is an enlarged side view of the relevant part.

FIG. 29 is an enlarged view illustrating a relevant part of an electronic device according to another variation of the second embodiment, wherein the upper portion is an enlarged plan view of the relevant part and the lower portion is an enlarged side view of the relevant part.

FIG. 30 is a plan view of an electronic device according to a third embodiment, with the sealing resin indicated by imaginary lines.

FIG. 31 is a plan view of an electronic device according to a fourth embodiment, with the sealing resin indicated by imaginary lines.

FIG. 32 is the schematic diagram of the electronic components of the electronic device according to the fourth embodiment.

FIG. 33 is a plan view of an electronic device according to a variation of the fourth embodiment, with the sealing resin indicated by imaginary lines.

FIG. 34 is a plan view of an electronic device according to a fifth embodiment.

FIG. 35 is a plan view of an electronic device according to a sixth embodiment.

### DETAILED DESCRIPTION OF EMBODIMENTS

The following describes preferred embodiments of the present disclosure in detail with reference to the drawings. In the following, identical or similar elements are denoted by the same reference signs, and redundant explanations are omitted. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Also, the expression “An object A (or the material thereof) contains a material C” includes “the object A (or the material thereof) is made of a material C” and “the object A (or the material thereof) is mainly composed of a material C”.

### First Embodiment

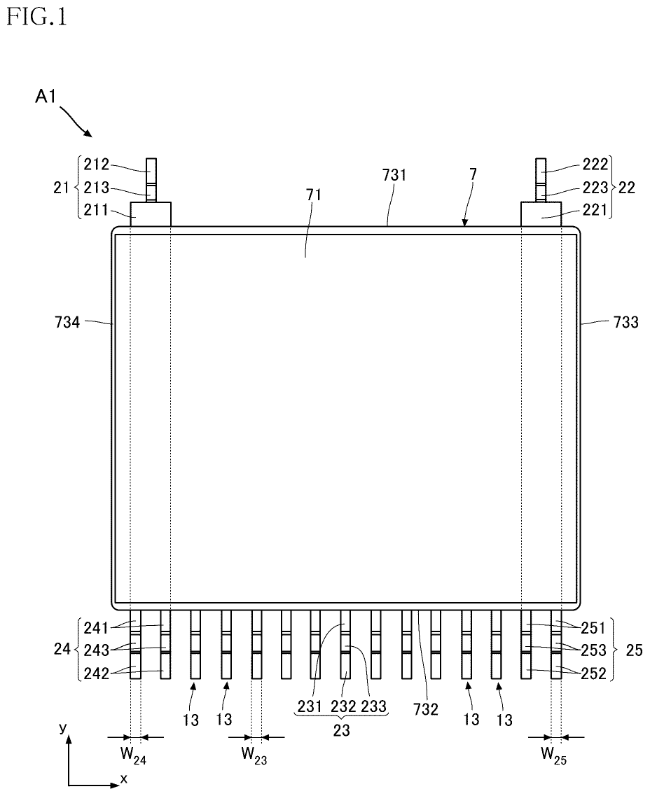

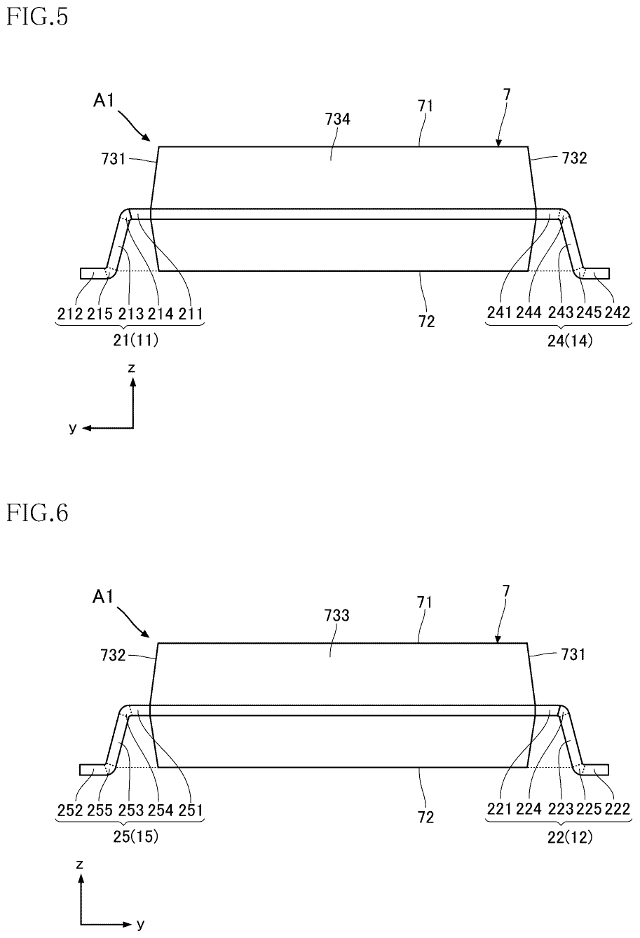

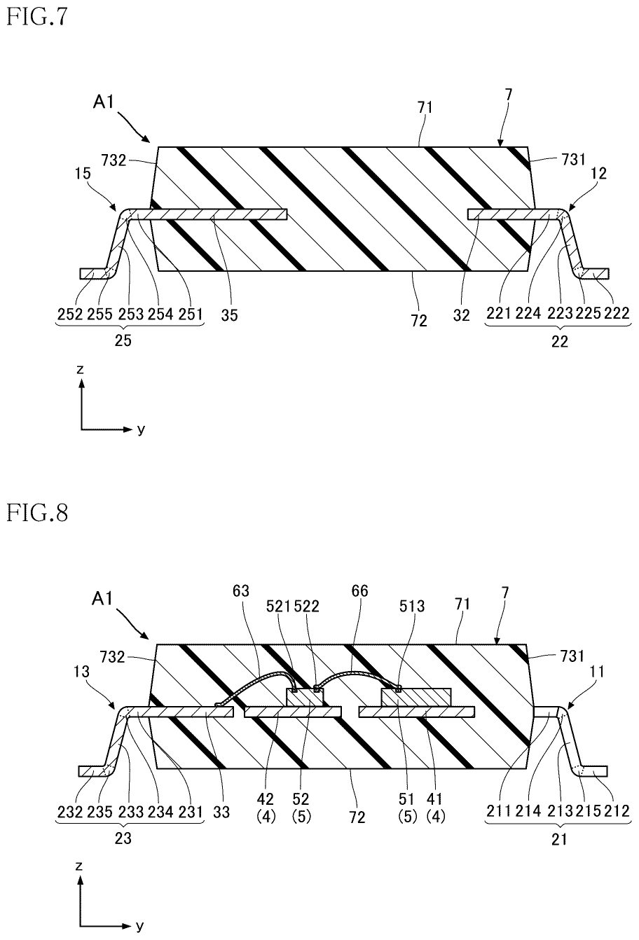

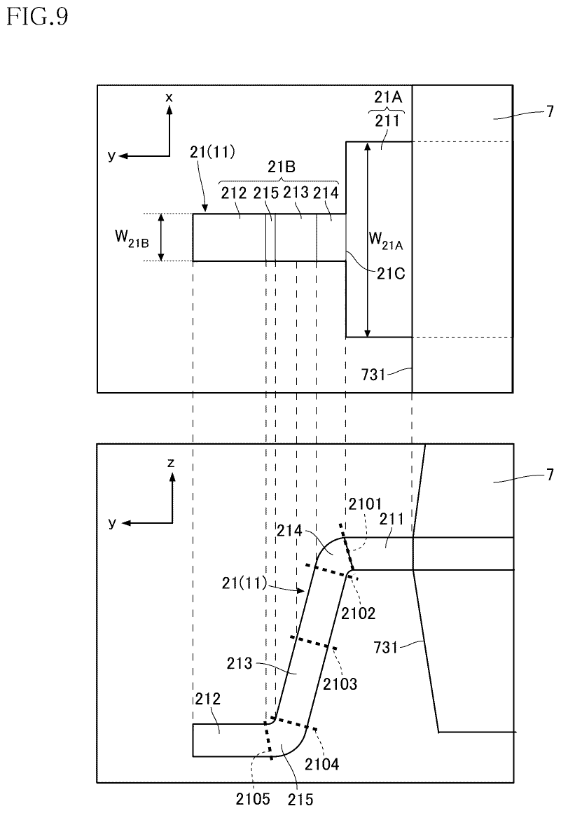

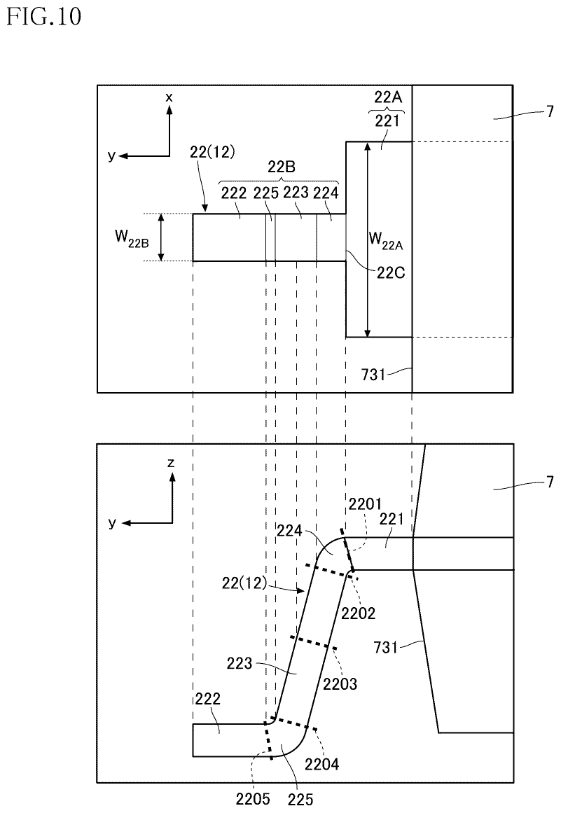

FIGS. 1 to 11 show an electronic device Al according to a first embodiment. The electronic device A1 includes a first lead 11, a second lead 12, a plurality of third leads 13, a fourth lead 14, a fifth lead 15, a die pad 4, an electronic component 5, a plurality of connection members 61 to 66, and a sealing resin 7. In the illustrated example, the electronic device A1 includes eleven third leads 13, and the number of the third leads 13 is not particularly limited. The specific use of the electronic device A1 is not particularly limited, and includes detecting the battery voltage of an electric vehicle, for example. The electronic device Al may be used not only for detecting the battery voltage of an electric vehicle but also for detecting other voltages in an electric vehicle, as well as voltages in industrial equipment, home appliances, power supplies, or the like. The electronic device A1 is a surface-mount semiconductor device and, in the present embodiment, is of a Small Outline Package (SOP) type, as shown in FIGS. 1 to 11.

For convenience of explanation, the thickness direction of the electronic device A1 is referred to as a “thickness direction z”. In the following description, “above”, “below”, “upper”, “lower”, “top surface” and “bottom surface” indicate the relative positional relationship of each component in the thickness direction z, and do not necessarily define the relationship with respect to the direction of gravity. The term “plan view” means as viewed in the thickness direction z. One direction orthogonal to the thickness direction z is referred to as a “first direction y”. The direction orthogonal to the thickness direction z and the first direction y is referred to as a “second direction x”.

The first lead 11, the second lead 12, the third leads 13, the fourth lead 14, the fifth lead 15 and the die pad 4 contain metals such as Cu (copper), Ni (nickel) and Fe (iron). The first lead 11, the second lead 12, the third leads 13, the fourth lead 14, the fifth lead 15 and the die pad 4 are formed from a single lead frame. The first lead 11, the second lead 12, the third leads 13, the fourth lead 14, the fifth lead 15 and the die pad 4 are formed, for example, by processing selected from punching, bending, or etching on a metal plate material. Each of the first lead 11, the second lead 12, the third leads 13, the fourth lead 14, the fifth lead 15 and the die pad 4 may be provided with a plating layer comprising Ag (silver), Ni, Au (gold) or the like at appropriate positions.

The first lead 11, the second lead 12, the third leads 13, the fourth lead 14 and the fifth lead 15 are electrically connected to the electronic component 5 and form a conductive path in the electronic device A1. The first lead 11, the second lead 12, the third leads 13, the fourth lead 14 and the fifth lead 15 are spaced apart from each other. The first lead 11, the second lead 12, the third leads 13, the fourth lead 14, and the fifth lead 15 each include a portion covered by the sealing resin 7 and a portion exposed from the sealing resin 7.

The first lead 11 includes an outer lead 21 and an inner lead 31. The outer lead 21 and the inner lead 31 are connected to each other and are integrally formed.

The outer lead 21 is a part of the first lead 11 that is exposed from the sealing resin 7. The outer lead 21 projects from the sealing resin 7 on one side of the first direction y. In plan view, the outer lead 21 has a rectangular shape with the first direction y as its longitudinal direction. The outer lead 21 is bent in a gull-wing shape as viewed in the second direction x. The outer lead 21 includes a root portion 211, a mounting portion 212, an extending portion 213, and two bent portions 214 and 215.

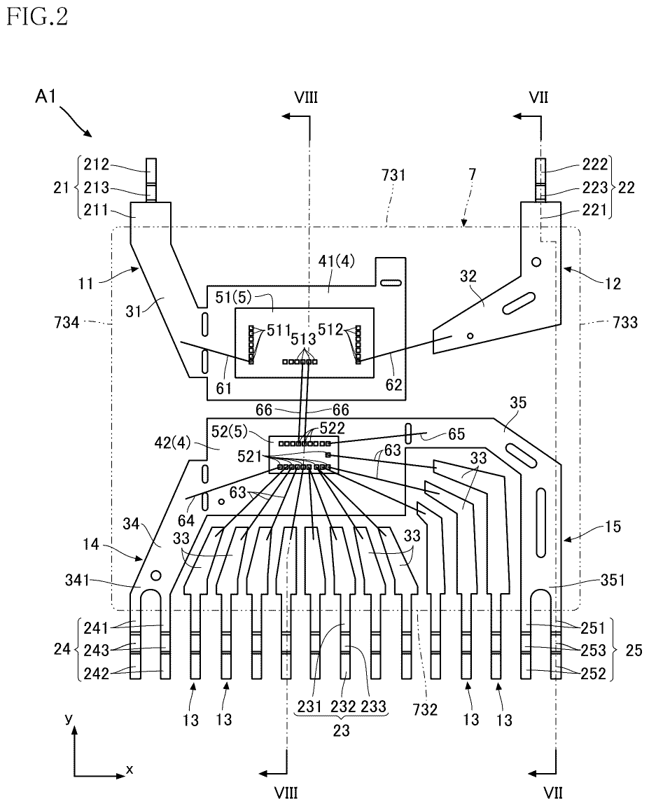

The root portion 211 is a base of the outer lead 21. As shown in FIGS. 1 and 2, the root portion 211 is located at the end of the outer lead 21 that is close to the sealing resin 7 in the first direction y. In other words, the root portion 211 is located closer to the sealing resin 7 than the mounting portion 212 and the extending portion 213 in the first direction y. The root portion 211 is located above the mounting portion 212 in the thickness direction z and projects from the center of the sealing resin 7 in the thickness direction z.

The mounting portion 212 is a tip of the outer lead 21. When the electronic device A1 is mounted on a circuit board, the mounting portion 212 is bonded to the circuit board. As shown in FIGS. 1 and 2, the mounting portion 212 is located at the end opposite to the sealing resin 7 in the first direction y. In other words, the mounting portion 212 is located farther from the sealing resin 7 than the root portion 211 and the extending portion 213 in the first direction y. The mounting portion 212 is located below the root portion 211 in the thickness direction z.

The extending portion 213 is connected to the root portion 211 through the bent portion 214 and to the mounting portion 212 through the bent portion 215. The extending portion 213 is inclined with respect to the root portion 211 and the mounting portion 212 as viewed in the second direction x. The extending portion 213 is also inclined with respect to the thickness direction z as viewed in the second direction x.

The bent portion 214 is interposed between the root portion 211 and the extending portion 213. The bent portion 214 is curved from the root portion 211 downwardly in the thickness direction z. The bent portion 215 is interposed between the mounting portion 212 and the extending portion 213. The bent portion 215 is curved from the mounting portion 212 upwardly in the thickness direction z. The two bent portions 214 and 215 are each curved as viewed in the second direction x.

As shown in FIG. 9, the outer lead 21 includes a first section 21A and a second section 21B. The first section 21A and the second section 21B are connected to each other. In the illustrated example, the first section 21A and the second section 21B are each rectangular in plan view. The first section 21A includes the root portion 211. The second section 21B includes the mounting portion 212. The first section 21A has a width (dimension in the second direction x) W_{21A} greater than a width (dimension in the second direction x) W₂₁₈ of the second section 21B. For example, the width W₂₁₈ is 2 to 6 times the width W_{21A}.

As understood from FIG. 9, a boundary (hereinafter referred to as a “first section boundary”) 21C between the first section 21A and the second section 21B is located between a boundary 2101, which is between the root portion 211 and the bent portion 214, and a central boundary 2103 of the extending portion 213. The central boundary 2103 of the extending portion 213 extends in the normal direction to the extending portion 213 at the center in an extending direction from the bent portion 214 to the bent portion 215. In the present embodiment, the first section boundary 21C overlaps with the boundary 2101. In the present disclosure, a boundary 2102 between the bent portion 214 and the extending portion 213 and a boundary 2104 between the bent portion 215 and the extending portion 213 are each parallel to the central boundary 2103. In such a configuration, the first section 21A includes the root portion 211, while the second section 21B includes the mounting portion 212, the extending portion 213, and the two bent portions 214 and 215.

The inner lead 31 is a part of the first lead 11 that is covered by the sealing resin 7. The inner lead 31 extends inward from the outer lead 21 toward the sealing resin 7.

The second lead 12 includes an outer lead 22 and an inner lead 32.

The outer lead 22 is a part of the second lead 12 that is exposed from the sealing resin 7. The outer lead 22 projects from the sealing resin 7 on one side of the first direction y. In plan view, the outer lead 22 has a rectangular shape with the first direction y as its longitudinal direction. In the present embodiment, the plan view shape of the outer lead 22 is congruent to the plan view shape of the outer lead 21, but unlike this configuration, these plan view shapes may not be congruent to each other. The outer lead 22 is bent in a gull-wing shape as viewed in the second direction x. The outer lead 22 overlaps with outer lead 21 as viewed in the second direction x. The outer lead 22 includes a root portion 221, a mounting portion 222, an extending portion 223, and two bent portions 224 and 225.

The mounting portion 222 is a tip of the outer lead 22. When the electronic device A1 is mounted on a circuit board, the mounting portion 222 is bonded to the circuit board. As shown in FIGS. 1 and 2, the mounting portion 222 is located at the end opposite to the sealing resin 7 in the first direction y. In other words, the mounting portion 222 is located farther from the sealing resin 7 than the root portion 221 and the extending portion 223 in the first direction y. The mounting portion 222 is located below the root portion 221 in the thickness direction z. The mounting portion 222 is aligned with the mounting portion 212 in the thickness direction z.

The root portion 221 is a base of the outer lead 22. As shown in FIGS. 1 and 2, the root portion 221 is located at the end of the outer leads 22 that is close to the sealing resin 7 in the first direction y. In other words, the root portion 221 is located closer to the sealing resin 7 than the mounting portion 222 and the extending portion 223 in the first direction y. The root portion 221 is located above the mounting portion 222 in the thickness direction z and projects from the center of the sealing resin 7 in the thickness direction z. The root portion 221 is aligned with the root portion 211 in the thickness direction z.

The extending portion 223 is connected to the root portion 221 through the bent portion 224 and to the mounting portion 222 through the bent portion 225. The extending portion 223 is inclined with respect to the mounting portion 222 and the root portion 221 as viewed in the second direction x.

The bent portion 224 is interposed between the root portion 221 and the extending portion 223. The bent portion 224 is curved from the root portion 221 downwardly in the thickness direction z. The bent portion 225 is interposed between the mounting portion 222 and the extending portion 223. The bent portion 225 is curved from the mounting portion 222 upwardly in the thickness direction z. The two bent portions 224 and 225 are each curved as viewed in the second direction x.

As shown in FIG. 10, the outer lead 22 includes a third section 22A and a fourth section 22B. The third section 22A and the fourth section 22B are connected to each other. The third section 22A includes the root portion 221. The fourth section 22B includes the mounting portion 222. The third section 22A has a width (dimension in the second direction x) W_{22A} greater than a width (dimension in the second direction x) W₂₂₈ of the fourth section 22B. For example, the width W_{22B} is 2 to 6 times the width W_{22A}. In the present embodiment, the width W_{21A} of the first section 21A and the width W_{22A} of the third section 22A are the same, and the width W₂₁₈ of the second section 21B and the width W₂₂₈ of the fourth section 22B are the same, but they may be different.

As understood from FIG. 10, a boundary (hereinafter referred to as a “second section boundary”) 22C between the third section 22A and the fourth section 22B is located between a boundary 2201, which is between the root portion 221 and the bent portion 224, and a central boundary 2203 of the extending portion 223. The central boundary 2203 of the extending portion 223 extends in the normal direction to the extending portion 223 at the center in an extending direction from the bent portion 224 to the bent portion 225. In the present embodiment, the second section boundary 22C overlaps with the boundary 2201. In the present disclosure, a boundary 2202 between the bent portion 224 and the extending portion 223 and a boundary 2204 between the bent portion 225 and the extending portion 223 are each parallel to the central boundary 2203. In this configuration, the third section 22A includes the root portion 221, while the fourth section 22B includes the mounting portion 222, the extending portion 223, and the two bent portions 224 and 225.

The inner lead 32 is a part of the second lead 12 that is covered by the sealing resin 7. The inner lead 32 is connected to the outer lead 22 and extends inward from the outer lead 22 toward the sealing resin 7.

The third leads 13 each include an outer lead 23 and an inner lead 33. Accordingly, the electronic device A1 includes a plurality of outer leads 23 and a plurality of inner leads 33. The outer leads 23 and the inner leads 33 are shared by each of the third leads 13, unless otherwise specifically noted.

The outer lead 23 is a part of each third lead 13 that is exposed from the sealing resin 7. Each outer lead 23 projects from the sealing resin 7 to the other side of the first direction y. In plan view, each outer lead 23 has a band-like shape with the first direction y as its longitudinal direction. The outer leads 23 are disposed at equal intervals along the second direction x. Each outer lead 23 is bent in a gull-wing shape as viewed in the second direction x. The outer leads 23 overlap with each other as viewed in the second direction x. The outer lead 23 includes a root portion 231, a mounting portion 232, an extending portion 233, and two bent portions 234 and 235. Thus, the electronic device A1 includes a plurality of root portions 231, a plurality of mounting portions 232, a plurality of extending portions 233, and a plurality of bent portions 234 and 235. The root portion 231, the mounting portion 232, the extending portion 233, and the two bent portions 234 and 235, described below, are shared by each of the outer leads 23, unless otherwise specifically noted.

The mounting portion 232 is a tip of the outer lead 23. When the electronic device A1 is mounted on a circuit board, the mounting portion 232 is bonded to the circuit board. As shown in FIGS. 1 and 2, the mounting portion 232 is located at the end opposite to the sealing resin 7 in the first direction y. In other words, the mounting portion 232 is located farther from the sealing resin 7 than the root portion 231 and the extending portion 233 in the first direction y. The mounting portion 232 is located below the root portion 231 in the thickness direction z. The mounting portions 232 are aligned with each other in the thickness direction z. The mounting portions 232 are disposed at equal intervals along the second direction x. Each mounting portion 232 has a width (dimension in the second direction x) W₂₃ (see FIG. 1) less than or equal to the width W₂₁₈ of the second section 21B and the width W₂₂₈ of the fourth section 22B. In other words, the width W_{21B} of the second section 21B and the width W₂₂₈ of the fourth section 22B are greater than or equal to the width W₂₃ of each mounting portion 232, respectively. In the present embodiment, the width W₂₃ of each mounting portion 232 is, for example, 0.15 mm or more and 0.5 mm or less.

The root portion 231 is a base of the outer lead 23. As shown in FIGS. 1 and 2, the root portion 231 is located at the end of the outer leads 23 that is close to the sealing resin 7 in the first direction y. In other words, the root portion 231 is located closer to the sealing resin 7 than the mounting portion 232 and the extending portion 233 in the first direction y. The root portion 231 is located above the mounting portion 232 in the thickness direction z and projects from the center of the sealing resin 7 in the thickness direction z. The root portions 231 are aligned with each other in the thickness direction z. The width (dimension in the second direction x) of the root portion 231 is equal to the width W₂₃ of the mounting portion 232.

The extending portion 233 connects the mounting portion 232 and the root portion 231. The extending portion 233 is inclined with respect to the mounting portion 232 and the root portion 231 as viewed in the second direction x. The width (dimension in the second direction x) of the extending portion 233 is equal to the width W₂₃ of the mounting portion 232.

The bent portion 234 is interposed between the root portion 231 and the extending portion 233. The bent portion 234 is curved from the root portion 231 downwardly in the thickness direction z. The bent portion 235 is interposed between the mounting portion 232 and the bent portion 234. The bent portion 235 is curved from the mounting portion 232 upwardly in the thickness direction z. The two bent portions 234 and 235 are each curved as viewed in the second direction x.

The inner lead 33 is the portion of each third lead 13 that is covered by the sealing resin 7. The inner lead 33 is connected to the outer lead 23 and extends inward from the outer lead 23 toward the sealing resin 7.

The fourth lead 14 includes an outer lead 24 and an inner lead 34.

The outer lead 24 is a part of the fourth lead 14 that is exposed from the sealing resin 7. The outer lead 24 projects from the sealing resin 7 to the other side of the first direction y. The outer lead 24 is located on the other side of the second direction x with respect to the outer leads 23. The outer lead 24 is bent in a gull-wing shape as viewed in the second direction x. The outer lead 24 overlaps with each outer lead 23 as viewed in the second direction x. The outer lead 24 includes a plurality of parts that are separated from each other. In the examples shown in FIGS. 1 and 2, it includes two separated parts. In plan view, each of the separated parts of the outer lead 24 has a rectangular shape with the first direction y as its longitudinal direction. In the present embodiment, the plan view shape of each of the separated parts is congruent to the plan view shape of the outer lead 23, but unlike this configuration, these plan view shapes may not be congruent to each other. Each of the separated parts of the outer lead 24 includes a root portion 241, a mounting portion 242, an extending portion 243, and two bent portions 244 and 245. Thus, in the example shown in FIGS. 1 and 2, the outer lead 24 includes two root portions 241, two mounting portions 242, two extending portions 243, and a plurality of bent portions 244 and 245. The root portion 241, the mounting portion 242, the extending portion 243, the bent portion 244 and the bent portion 245, described below, are shared by each of the separated parts of the outer lead 24, unless otherwise specifically noted.

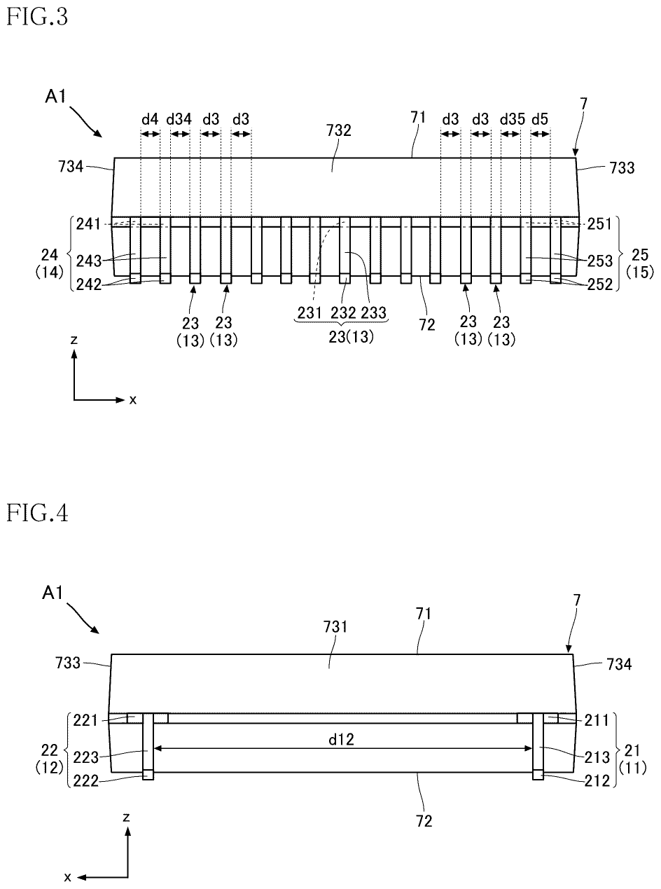

The mounting portion 242 is a tip of each of the separated parts of the outer lead 24. When the electronic device A1 is mounted on a circuit board, the mounting portion 242 is bonded to the circuit board. As shown in FIGS. 1 and 2, the mounting portion 242 is located at the end opposite to the sealing resin 7 in the first direction y. In other words, the mounting portion 242 is located farther from the sealing resin 7 than the root portion 241, the extending portion 243, and the two bent portions 244 and 245 in the first direction y. The mounting portion 242 is located below the root portion 241 in thickness direction z. The mounting portion 242 is aligned with each mounting portion 232 in the thickness direction z. The two mounting portions 242 are adjacent to each other in the second direction x on the other side of the second direction x with respect to the mounting portions 232. Each of the two mounting portions 242 has a width (dimension in the second direction x) W₂₄ (see FIG. 1), for example, equal to the width W₂₃ of each mounting portion 232. The width W₂₄ of each of the two mounting portions 242 may also be equal to the width W₂₁₈ of the second section 21B. In the present embodiment, the width W₂₄ of each of the two mounting portions 242 is, for example, 0.15 mm or more and 0.5 mm or less. A spacing d4 between the two mounting portions 242 (see FIG. 3) is equal to a spacing d3 between the two mounting portions 232 adjacent in the second direction x. Among the two mounting portions 242, the one located on the other side of the second direction x includes an end on the other side of the second direction x, which overlaps with the end of the first section 21A on the other side of the second direction x, as viewed in the first direction y. Among the two mounting portions 242, the one located on one side of the second direction x includes an end on one side of the second direction x, which overlaps with the end of the first section 21A on one side of the second direction x, as viewed in the first direction y.

The root portion 241 is a base of each separated part of the outer lead 24. As shown in FIGS. 1 and 2, the root portion 241 is located at the end of each separated part of the outer lead 24 that is close to the sealing resin 7 in the first direction y. In other words, the root portion 241 is located closer to the sealing resin 7 than the mounting portion 242, the extending portion 243, and the two bent portions 244 and 245 in the first direction y. The root portion 241 is located above the mounting portion 242 in the thickness direction z and projects from the center of the sealing resin 7 in the thickness direction z. The root portion 241 is aligned with each root portion 231 in the thickness direction z. The width (dimension in the second direction x) of each of the two root portions 241 is equal to the width W₂₄ of each of the two mounting portions 242.

The extending portion 243 is connected to the root portion 241 through the bent portion 244 and to the mounting portion 242 through the bent portion 245. The extending portion 243 is inclined with respect to the root portion 241 and the mounting portion 242 as viewed in the second direction x. The width (dimension in the second direction x) of the extending portion 243 is equal to the width W₂₄ of the root portion 241. The bent portion 244 is interposed between the root portion 241 and the extending portion 243. The bent portion 244 is curved from the root portion 241 downwardly in the thickness direction z. The bent portion 245 is interposed between the mounting portion 242 and the extending portion 243. The bent portion 245 is curved from the mounting portion 242 upwardly in the thickness direction z. The two bent portions 244 and 245 are each curved as viewed in the second direction x.

The inner lead 34 is a part of the fourth lead 14 that is covered by the sealing resin 7. The inner lead 34 is connected to the outer lead 24 and extends inward from the outer lead 24 toward the sealing resin 7. The inner lead 34 includes a branched portion 341, as shown in FIG. 2. The branched portion 341 is located at the end of the inner lead 34 that is connected to the outer lead 24. The branched portion 341 is connected to each of the root portions 241. The branched portion 341 includes the same number of branches as the number of root portions 241. Thus, in a configuration where the outer lead 24 includes the two root portions 241, the branched portion 341 includes two branches. The branched portion 341 includes the ends of branches from which the two respective root portions 241 extend. Hence, the two mounting portions 242 of the outer lead 24 have the same potential.

The fifth lead 15 includes an outer lead 25 and an inner lead 35.

The outer lead 25 is a part of the fifth lead 15 that is exposed from the sealing resin 7. As shown in FIG. 2, the outer lead 25 projects from the sealing resin 7 to the other side of the first direction y. The outer lead 25 is located on one side of the second direction x with respect to the outer leads 23. The outer lead 25 is bent in a gull-wing shape as viewed in the second direction x. The outer lead 25 overlaps with each outer lead 23 as viewed in the second direction x. The outer lead 25 includes a plurality of parts that are separated from each other. In the examples shown in FIGS. 1 and 2, it includes two separated parts. In plan view, each of the separated parts of the outer lead 25 has a rectangular shape with the first direction y as its longitudinal direction. In the present embodiment, the plan view shape of each of the separated parts is congruent to the plan view shape of the outer lead 23, but unlike this configuration, these plan view shapes may not be congruent to each other. Each of the separated parts of the outer lead 25 includes a root portion 251, a mounting portion 252, an extending portion 253, and two bent portions 254 and 255. Thus, in the example shown in FIGS. 1 and 2, the outer lead 25 includes two root portions 251, two mounting portions 252, two extending portions 253, and a plurality of bent portions 254 and 255. The root portion 251, the mounting portion 252, the extending portion 253, the bent portion 254 and the bent portion 255, described below, are shared by each of the separated parts of the outer lead 25, unless otherwise specifically noted.

The mounting portion 252 is a tip of each of the separated parts of the outer lead 25. When the electronic device A1 is mounted on a circuit board, the mounting portion 252 is bonded to the circuit board. In FIGS. 1 and 2, the mounting portion 252 is located at the end opposite to the sealing resin 7 in the first direction y. In other words, the mounting portion 252 is located farther from the sealing resin 7 than the root portion 251, the extending portion 253, and the two bent portions 254 and 255 in the first direction y. The mounting portion 252 is located below the root portion 251 in thickness direction z. The mounting portion 252 is aligned with each mounting portion 232 in the thickness direction z. The two mounting portions 252 are adjacent to each other in the second direction x on one side of the second direction x with respect to the mounting portions 232. Each of the two mounting portions 252 has a width (dimension in the second direction x) W₂₅ (see FIG. 1), for example, equal to the width W₂₃ of each mounting portion 232. The width W₂₅ of each of the two mounting portions 252 may also be equal to the width W_{21B} of the second section 21B. In the present embodiment, the width W₂₅ of each of the two mounting portions 252 is, for example, 0.15 mm or more and 0.5 mm or less. A spacing d5 between the two mounting portions 252 (see FIG. 3) is equal to the spacing d3 between the two adjacent mounting portions 232 in the second direction x. Among the two mounting portions 252, the one located on the other side of the second direction x includes an end on the other side of the second direction x, which overlaps with the end of the third section 22A on the other side of the second direction x, as viewed in the first direction y. Among the two mounting portions 252, the one located on one side of the second direction x includes an end on one side of the second direction x, which overlaps with the end of the third section 22A on one side of the second direction x, as viewed in the first direction y.

The root portion 251 is a base of each separated part of the outer lead 25. As shown in FIGS. 1 and 2, the root portion 251 is located at the end of each separated part of the outer lead 25 that is close to the sealing resin 7 in the first direction y. In other words, the root portion 251 is located closer to the sealing resin 7 than the mounting portion 252 and the extending portion 253 in the first direction y. The root portion 251 is located above the mounting portion 252 in the thickness direction z and projects from the center of the sealing resin 7 in the thickness direction z. The root portion 251 is aligned with each root portion 231 in the thickness direction z. The width (dimension in the second direction x) of each of the two root portions 251 is equal to the width W₂₅ of each of the two mounting portions 252.

The extending portion 253 is connected to the root portion 251 through the bent portion 254 and to the mounting portion 252 through the bent portion 255. The extending portion 253 is inclined with respect to the root portion 251 and the mounting portion 252 as viewed in the second direction x. The width (dimension in the second direction x) of the extending portion 253 is equal to the width W₂₅ of the root portion 251.

The bent portion 254 is interposed between the root portion 251 and the extending portion 253. The bent portion 254 is curved from the root portion 251 downwardly in the thickness direction z. The bent portion 255 is interposed between the mounting portion 252 and the extending portion 253. The bent portion 255 is curved from the root portion 251 upwardly in the thickness direction z. The two bent portions 254 and 255 are each curved as viewed in the second direction x.

The inner lead 35 is a part of the fifth lead 15 that is covered by the sealing resin 7. The inner lead 35 is connected to the outer lead 25 and extends inward from the outer lead 25 toward the sealing resin 7. The inner leads 33 are located between the two inner leads 34 and 35. The inner lead 35 includes a branched portion 351, as shown in FIG. 2. The branched portion 351 is located at the end of the inner lead 35 that is connected to the outer lead 25. The branched portion 351 is connected to each of the root portions 251. The branched portion 351 includes the same number of branches as the number of root portions 251. Thus, in a configuration where the outer lead 25 includes the two root portions 251, the branched portion 351 includes two branches. The branched portion 351 includes ends of branches from which the two respective root portions 251 extend. Hence, the two mounting portions 252 of the outer lead 25 have the same potential.

In the electronic device A1, the mounting portion 212 and the mounting portion 222 are adjacent to each other with a spacing d12 (see FIG. 4) along the second direction x. The mounting portions 232 are arranged with the spacing d3 (see FIG. 3) along the second direction x. The spacing d12 (see FIG. 4) along the second direction x between the mounting portion 212 and the mounting portion 222 is greater than the spacing d3 (see FIG. 3) along the second direction x between the two mounting portions 232 adjacent in the second direction x. The spacing d12 may be 10 to 20 times the spacing d3. In the present embodiment, the spacing d12 may be 5 mm or more and 10 mm or less, and the spacing d3 may be 0.25 mm or more and 5 mm or less. Given that the potential difference between the mounting portion 212 and the mounting portion 222 is about 800 V, the spacing d12 is preferably 4 mm or more. The spacing d3 is equal to a spacing d34 (see FIG. 3) along the second direction x between one of the two mounting portions 242 and its adjacent mounting portion 232, and to a spacing d35 (see FIG. 3) between one of the two mounting portions 252 and its adjacent mounting portion 232.

The die pad 4 supports the electronic component 5. The die pad 4 includes a first pad 41 and a second pad 42. The first pad 41 and the second pad 42 are spaced apart from each other. The respective plan view shapes of the first pad 41 and the second pad 42 are not particularly limited but are rectangular in the illustrated example. As shown in FIG. 2, the first pad 41 and the second pad 42 may be aligned in the first direction y, and the first pad 41 is offset on one side of the first direction y with respect to the second pad 42. As shown in FIG. 2, the first pad 41 is connected to the inner lead 31. The first pad 41 and the first lead 11 are integrally formed. The second pad 42 is connected to the two inner leads 34 and 35. The second pad 42, the fourth lead 14 and the fifth lead 15 are integrally formed.

In the electronic device A1, the respective shapes and positional relationships of the die pad 4 and each of the inner leads 31, 32, 33, 34 and 35 are not limited to the illustrated example, and may be changed according to the specifications of the electronic device A1.

The electronic component 5 is an element to perform an electrical function in the electronic device A1. The specific function of the electronic component 5 is not particularly limited, but in the present embodiment, the electronic component 5 has the function of detecting voltage. In the illustrated example, the electronic component 5 includes a first chip 51 and a second chip 52 that are separated from each other.

The first chip 51 is mounted on the first pad 41. In the present embodiment, the first chip 51 sends a first signal according to the potential of the first lead 11 and a second signal according to the potential of the second lead 12 to the second chip 52. The first chip 51 includes a plurality of electrodes 511, 512 and 513 on its top surface in the thickness direction z.

The second chip 52 is mounted on the second pad 42. In the present embodiment, the second chip 52 receives the first signal and the second signal from the first chip 51 and sends a third signal according to the potential difference between the first lead 11 and the second lead 12. In other words, the second chip 52 sends a detection signal (third signal) of the voltage applied between the first lead 11 and the second lead 12. The second chip 52 includes pluralities of electrodes 521 and 522 on its top surface in the thickness direction z.

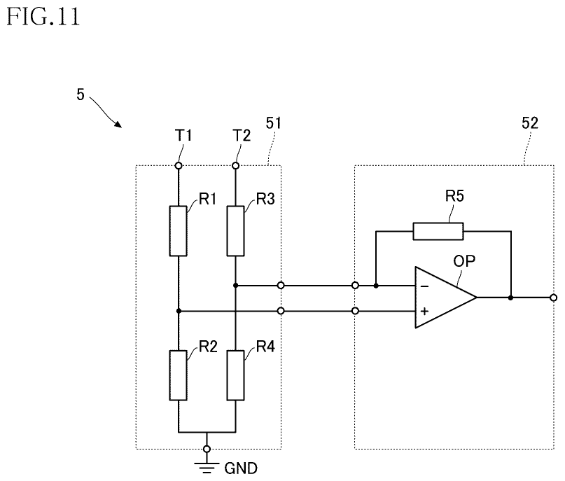

In the electronic device A1, the electronic component 5 (the first chip 51 and the second chip 52) includes circuity shown in FIG. 11, for example. As shown in FIG. 11, the first chip 51 includes a plurality of resistor elements R1 to R4, and the second chip 52 includes an operational amplifier OP and a resistor element R5. The circuity of the electronic component 5 is not limited to the example shown in FIG. 11.

The two resistor elements R1 and R2 are connected in series with each other. The two resistor elements R1 and R2 divide a voltage at a terminal T1 (potential difference between a potential of a terminal T1 and a reference potential of a ground GND). In the present embodiment, the terminal T1 corresponds to each electrode 512. The connection point of the two resistor elements R1 and R2 is connected to a non-inverting input terminal of the operational amplifier OP. The two resistor elements R3 and R4 are connected in series with each other. The two resistor elements R3 and R4 divide a voltage of a terminal T2 (potential difference between a potential of a terminal T2 and a reference potential of a ground GND). In the present embodiment, the terminal T2 corresponds to each electrode 511. The connection point of the two resistor elements R3 and R4 is connected to an inverting input terminal of the operational amplifier OP. When the electronic device A1 detects the voltage of a battery installed in an electric vehicle, the terminal T1 and the terminal T2 are electrically connected to the high-potential side terminal and the low-potential side terminal, respectively.

The operational amplifier OP receives the first signal according to the potential of the terminal T1 (in the present embodiment, a signal of the divided voltage of the terminal T1) and the second signal according to the potential of the terminal T2 (in the present embodiment, a signal obtained of the divided voltage of the terminal T2), and sends the third signal according to the potential difference between the terminal T1 and the terminal T2. The resistor element R5 is an element for determining the amplification gain of the operational amplifier OP (i.e., a feedback resistor), and one end of the resistor element R5 is connected to the inverting input terminal of the operational amplifier OP, and the other end is connected to the output terminal of the operational amplifier OP. The second chip 52 does not necessarily include the resistor element R5.

The plurality of connection members 61 to 66 each electrically connects the parts spaced apart from each other. In the illustrated example, each connection member 61 to 66 is a bonding wire. Alternatively, each connection member 61 to 66 may be a metal plate instead of a bonding wire. The connection members 61 to 66 each contain Au, Al (aluminum), or Cu.

As shown in FIG. 2, the connection member 61 is bonded to the electrode 511 of the first chip 51 and the inner lead 31, and electrically connects the first chip 51 and the first lead 11. In other words, the outer lead 21 of the first lead 11 is electrically connected to the first chip 51 of the electronic component 5 via the connection member 61.

As shown in FIG. 2, the connection member 62 is bonded to the electrode 512 of the first chip 51 and the inner lead 32, and electrically connects the first chip 51 and the second lead 12. In other words, the outer lead 22 of the second lead 12 is electrically connected to the first chip 51 of the electronic component 5 via the connection member 62.

As shown in FIG. 2, the connection members 63 are bonded to the respective electrodes 521 of the second chip 52 and the respective inner leads 33, and electrically connect the second chip 52 and the respective third leads 13. In other words, the outer lead 23 of each third lead 13 is electrically connected to the second chip 52 of the electronic component 5 via one of the connection members 63.

As shown in FIG. 2, the connection member 64 is bonded to the electrode 521 of the second chip 52 and the inner leads 34, and electrically connect the second chip 52 and the fourth lead 14. In other words, the outer lead 24 of the fourth lead 14 is electrically connected to the second chip 52 of the electronic component 5 via the connection member 64.

As shown in FIG. 2, the connection member 65 is bonded to the electrode 521 of the second chip 52 and the inner lead 35, and electrically connects the second chip 52 and the fifth lead 15. In other words, the outer lead 25 of the fifth lead 15 is electrically connected to the second chip 52 of the electronic component 5 via the connection member 65.

As shown in FIG. 2, the connection members 66 are each bonded to the electrode 513 of the first chip 51 and the electrode 522 of the second chip 52, and electrically connect the first chip 51 and the second chip 52. Hence, the connection members 66 form transmission paths for the first signal and the second signal.

The sealing resin 7 covers the die pad 4 (the first pad 41 and the second pad 42), the electronic component 5 (the first chip 51 and the second chip 52), the connection members 61 to 66, and a part of each of the first lead 11, the second lead 12, the third leads 13, the fourth lead 14, and the fifth lead 15. The sealing resin 7 contains an insulative material such as epoxy resin, for example. Preferably, the sealing resin 7 is made of a resin material with a CTI (Comparative Tracking Index) of 600 V or higher. The sealing resin 7 has, for example, a cuboid. The sealing resin 7 has a dimension along the second direction x of, for example, 5 mm to 10 mm and a dimension along the first direction y of, for example, 3 mm to 13 mm. The sealing resin 7 includes a resin obverse surface 71, a resin reverse surface 72, and a plurality of resin side surfaces 731 to 734.

The resin obverse surface 71 and the resin reverse surface 72 are spaced apart from each other in the thickness direction z. The resin obverse surface 71 faces one side of the thickness direction z, and the resin reverse surface 72 faces the other side of the thickness direction z. The resin obverse surface 71 is a top surface of the sealing resin 7, and the resin reverse surface 72 is a bottom surface of the sealing resin 7.

The paired resin side surfaces 731 and 732 are spaced apart from each other in the first direction y. The resin side surface 731 faces one side of the first direction y, and the resin side surface 732 faces the other side of the first direction y. The paired resin side surfaces 733 and 734 are spaced apart from each other in the second direction x. The resin side surface 733 faces one side of the second direction x, and the resin side surface 734 faces the other side of the second direction x.

As shown in FIGS. 1, 2 and 4 to 6, the two outer leads 21 and 22 each project from the resin side surface 731. As shown in FIGS. 1 to 3, 5 and 6, the outer leads 23, 24 and 25 each project from the resin side surface 732.

The operative effects of the electronic device A1 are as follows.

In the electronic device A1, the outer lead 21 includes the root portion 211, the mounting portion 212, and the extending portion 213 that is connected to the root portion 211 through the bent portion 214 and to the mounting portion 212 through the bent portion 215. Further, the outer lead 21 includes the first section 21A including the root portion 211 and the second section 21B including the mounting portion 212. The width (dimension in the second direction x) W_{21A} of the first section 21A is greater than the width (dimension in the second direction x) W₂₁₈ of the second section 21B. Studies by the inventor of the present application have revealed the following in such a configuration where the width of the root portion 211 (the width W_{21A} of the first section 21A) is greater than the width of the mounting portion 212 (the width W_{21B} of the second section 21B). That is, it has been revealed that the variation in the shape of the outer lead 21 is suppressed when the first section boundary 21C between the first section 21A and the second section 21B is disposed between the boundary 2101, which is between the root portion 211 and the bent portion 214, and the central boundary 2103 of the extending portion 213, as compared to the case, for example, where the first section boundary 21C is disposed at the boundary 2104 (see FIG. 9) between the extending portion 213 and the bent portion 215 or at the boundary 2105 (see FIG. 9) between the mounting portion 212 and the bent portion 215. The electronic device A1 includes the first section boundary 21C located between the boundary 2101, which is between the root portion 211 and the bent portion 214, and the central boundary 2103 of the extending portion 213, thereby suppressing the variation of the shape of the outer lead 21. Thus, it is possible to reduce poor bonding between the electronic device A1 and the circuit board. In the electronic device A1, the first section boundary 21C is located between the boundary 2101, which is between the root portion 211 and the bent portion 214, and the boundary 2102 between the bent portion 214 and the extending portion 213. Studies by the inventor of the present application have revealed that the closer the first section boundary 21C is to the boundary 2101 than to the central boundary 2103, the less the variation in the shape of the outer lead 21 is. Therefore, since the first section boundary 21C is located between the boundary 2101 and the boundary 2102, thereby further suppressing the variation in the shape of the outer lead 21 in the electronic device A1. In particular, in the electronic device A1, the first section boundary 21C overlaps with the boundary 2101 between the root portion 211 and the bent portion 214, which preferably suppresses the variation in the shape of the outer lead 21.

In the electronic device A1, the outer lead 22 includes the root portion 221, the mounting portion 222, and the extending portion 223 that is connected to the root portion 221 through the bent portion 224 and to the mounting portion 222 through the bent portion 225. Further, the outer lead 22 includes the third section 22A including the root portion 221 and the fourth section 22B including the mounting portion 222. The width (dimension in the second direction x) W_{22A} of the third section 22A is greater than the width (dimension in the second direction x) W₂₂₈ of the fourth section 22B. The second section boundary 22C between the third section 22A and the fourth section 22B is disposed between the boundary 2201 (see FIG. 10) between the root portion 221 and the bent portion 224 and the central boundary 2203 (see FIG. 10) of the extending portion 223. Thus, as with the outer lead 21, the variation in the shape of the outer lead 22 is suppressed in the electronic device A1, as compared to the case where second section boundary 22C is, for example, disposed at the boundary 2204 (see FIG. 10), which is between the extending portion 223 and the bent portion 225, or at the boundary 2205 (see FIG. 10) between the mounting portion 222 and the bent portion 225.

In the electronic device A1, the second section boundary 22C is located between the boundary 2201, which is between the root portion 221 and the bent portion 224, and the boundary 2202 (see FIG. 10) between the bent portion 224 and the extending portion 223. Thus, it is possible to further suppress the variation in the shape of the outer lead 22 in the electronic device A1, as with the outer lead 21. In particular, in the electronic device A1, the second section boundary 22C overlaps with the boundary 2201 between the root portion 221 and the bent portion 224, which preferably suppresses the variation in the shape of the outer lead 22.

In the electronic device A1, the two outer leads 21 and 22 are adjacent to each other in the second direction x with the spacing d12, and the outer leads 23 are arranged in the second direction x with the spacing d3. The spacing d12 is greater than the spacing d3. Such a configuration increases the creepage distance between the two outer leads 21 and 22 (distance along the surface of the sealing resin 7) rather than the creepage distance between the outer leads 23 (distance along the surface of the sealing resin 7), so that discharge is less likely to occur between the two outer leads 21 and 22 even when a high voltage is applied between the two outer leads 21 and 22. Hence, in the electronic device A1, discharge between the two outer leads 21 and 22 can be suppressed while reducing the device size. In other words, the electronic device A1 has a favorable package structure for suppressing electrical discharges between the two outer leads 21 and 22.

In a configuration where the spacing d12 is greater than the spacing d3 as described above, the variation in the shape of the two outer leads 21 and 22 tends to be greater than the variation in the shape of the outer leads 23. Therefore, as described above, the first section boundary 21C is disposed between the boundary 2101 and the central boundary 2103 and the second section boundary 22C is disposed between the boundary 2201 and the central boundary 2203, which is preferable in suppressing the variation of the shape of the two outer leads 21 and 22 in a package structure where the spacing d12 is greater than the spacing d3.

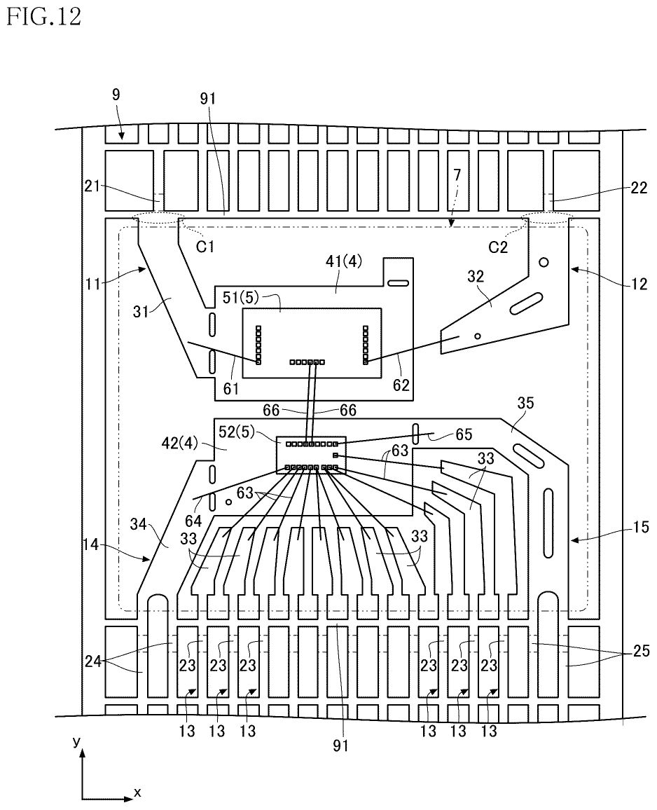

In the electronic device A1, the first section 21A includes the root portion 211. In the manufacturing process of the electronic device A1, the first lead 11, the second lead 12, the third leads 13, the fourth lead 14, and the fifth lead 15 are, as shown in FIG. 12, connected to each other through the tie bar 91 and included in the single lead frame 9. This tie bar 91 is, for example, connected to the root portion 211 of the first lead 11, the root portion 221 of the second lead 12, the root portion 231 of each third lead 13, the root portion 241 of the fourth lead 14, and the root portion 251 of the fifth lead 15. In the lead frame 9, the inner lead 31 is held by the tie bar 91 at the connection point C1 shown in FIG. 12. Hence, the load of the inner lead 31 is applied to the connection point C1. In particular, in the electronic device A1, the inner lead 31 is connected to the first pad 41, so that the load on the first pad 41 is also applied to the connection point C1, thereby further increasing the load on the connection point C1. For example, in the manufacturing process of the electronic device A1, loads will be applied to the inner lead 31 and the first pad 41 during transporting the lead frame 9, bonding the first chip 51 to the first pad 41, and bonding each of the connection members 61 and 62. If the strength of the connection point C1 is insufficient to withstand such loads, the first lead 11 may become deformed (e.g., the connection point C1 may bend in the direction of gravity or in the direction of the pressure applied during bonding the first chip 51). On the other hand, the electronic device Al can appropriately secure the width of the connection point C1, as the width (dimension in the second direction x) W_{21A} of the first section 21A is greater than the width (dimension in the second direction x) W_{21B} of the second section 21B. This improves the strength of the connection point C1, thereby suppressing deformation of the first lead 11. In other words, the deformation of the first lead 11 in the electronic device A1 can be suppressed.

The same is true for the second lead 12. That is, the electronic device A1 can appropriately secure the width of the connection point C2 (see FIG. 12), as the third section 22A includes the root portion 221, and the width (dimension in the second direction x) W_{22A} of the third section 22A is greater than the width (dimension in the second direction x) W_{22B} of the fourth section 22B. This improves the strength of the connection point C2, thereby suppressing deformation of the second lead 12 in the electronic device A1.

Other embodiments and variations of the electronic device of the present disclosure are described below. Various parts of embodiments and variations may be selectively used in any appropriate combination as long as it is technically compatible.

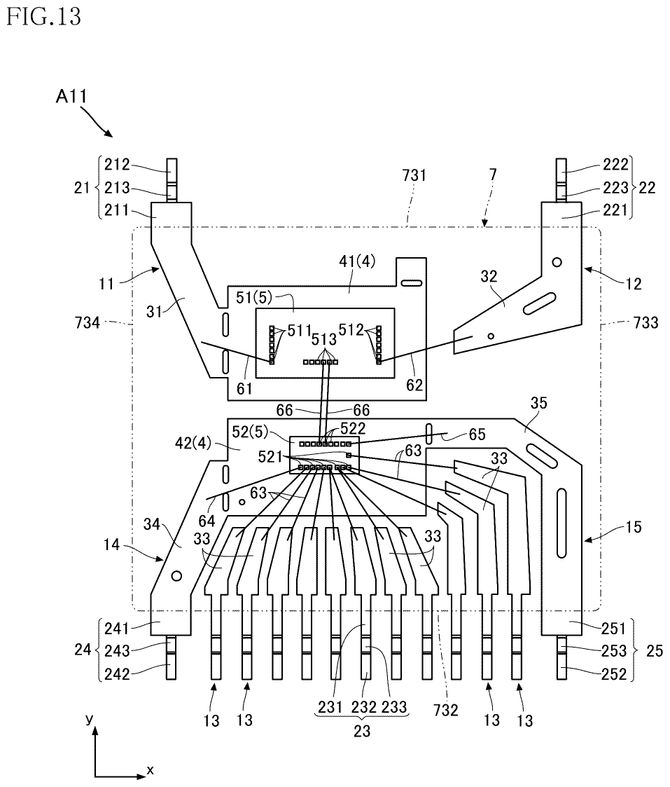

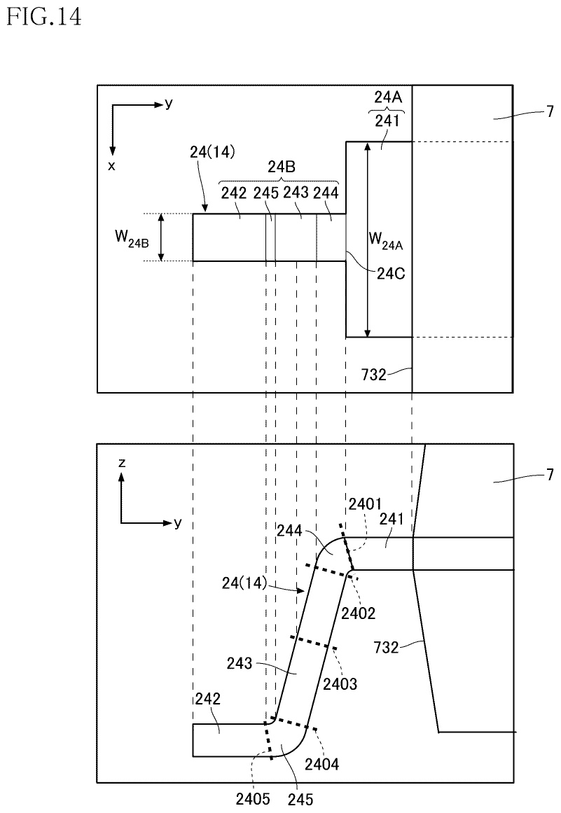

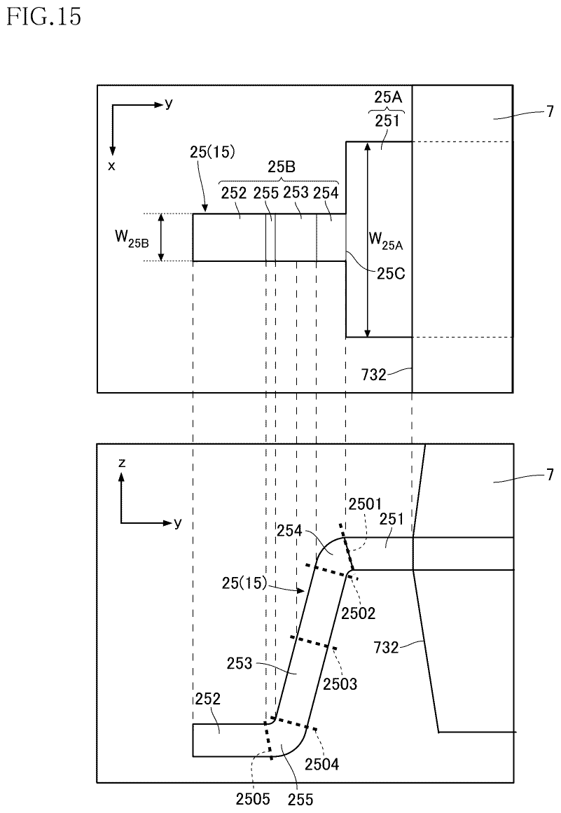

FIGS. 13 to 15 show an electronic device A11 according to a variation of the first embodiment. The electronic device A11 differs from the electronic device A1 in the following points. In the electronic device A11, each outer lead 24 and 25 shares the same shape as the outer lead 21 (the outer lead 22).

The outer lead 24 of the electronic device A11 includes the root portion 241, the mounting portion 242, the extending portion 243 and the two bent portions 244 and 245. Thus, the outer lead 24 of the electronic device A11 is not separated into multiple parts.

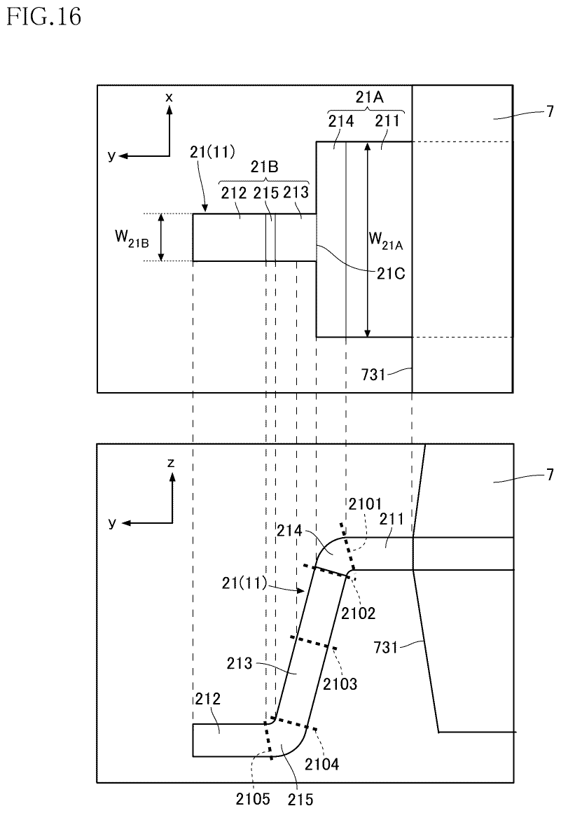

As shown in FIG. 14, the outer lead 24 of the electronic device A11 includes two sections 24A and 24B. The two sections 24A and 24B are connected to each other. The section 24A includes the root portion 241. The section 24B includes the mounting portion 242. The section 24A has a width (dimension in the second direction x) W_{24A} greater than a width (dimension in the second direction x) W₂₄₈ of the section 24B. In one example, the width W_{24B} is 2 to 6 times the width W_{24A}.

As understood from FIG. 14, a section boundary 24C between the two sections 24A and 24B is located between the boundary 2401, which is between the root portion 241 and the bent portion 244, and the central boundary 2403 of the extending portion 243. The central boundary 2403 of the extending portion 243 extends in the normal direction to the extending portion 243 at the center in an extending direction from the bent portion 244 to the bent portion 245. In the present embodiment, the section boundary 24C overlaps with the boundary 2401. In the present disclosure, the boundary 2402 between the bent portion 244 and the extending portion 243 and the boundary 2404 between the bent portion 245 and the extending portion 243 are each parallel to the central boundary 2403. In such a configuration, the section 24A includes the root portion 241, while the section 24B includes the mounting portion 242, the extending portion 243, and the two bent portions 244 and 245.

The outer lead 25 of the electronic device A11 includes the root portion 251, the mounting portion 252, the extending portion 253 and the two bent portions 254 and 255. Thus, the outer lead 25 of the electronic device A11 is not separated into multiple parts.

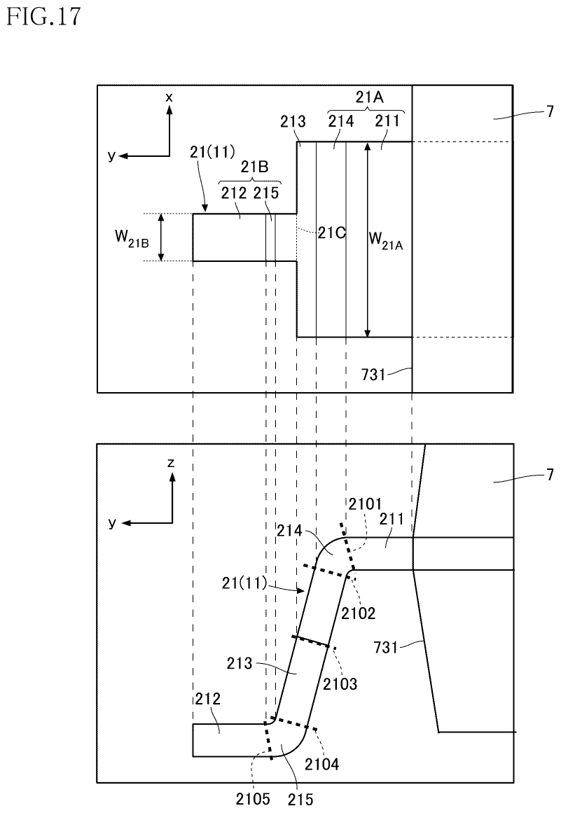

As shown in FIG. 15, the outer lead 25 of the electronic device A11 includes two sections 25A and 25B. The two sections 25A and 25B are connected to each other. The section 25A includes the root portion 251. The section 25B includes the mounting portion 252. The section 25A has a width (dimension in the second direction x) W_{25A} greater than a width (dimension in the second direction x) W_{25B} of the section 25B. In one example, the width W_{25B} is 2 to 6 times the width W_{25A}.

As understood from FIG. 15, a section boundary 25C between the two sections 25A and 25B is located between the boundary 2501, which is between the root portion 251 and the bent portion 254, and the central boundary 2503 of the extending portion 253. The central boundary 2503 of the extending portion 253 extends in the normal direction to the extending portion 253 at the center in an extending direction from the bent portion 254 to the bent portion 255. In the present embodiment, the section boundary 2520 C. overlaps with the boundary 2501. In the present disclosure, the boundary 2502 between the bent portion 254 and the extending portion 253 and the boundary 2504 between the bent portion 255 and the extending portion 253 are each parallel to the central boundary 2503. In such a configuration, the section 25A includes the root portion 251, while the section 25B includes the mounting portion 252, the extending portion 253, and the two bent portions 254 and 255.

The variation in the shape of each of the outer leads 21 and 22 in the electronic device A11 can be suppressed, as with the electronic device A1. In addition, the electronic device A11 may have a configuration in common with the electronic device A1, thereby achieving the same effect as the electronic device A1.

Further, in the electronic device A11, the outer lead 24 is configured in the same manner as the outer lead 21 (the outer lead 22). Hence, the variation in the shape of the outer lead 24 can be suppressed in the electronic device A11, as compared to the case where the section boundary 24C is, for example, disposed at the boundary 2404 (see FIG. 14) between the extending portion 243 and the bent portion 245 or at the boundary 2405 (see FIG. 14) between the mounting portion 242 and the bent portion 245. Similarly, the outer lead 25 is configured in the same manner as the outer lead 21 (the outer lead 22). Hence, the variation in the shape of the outer lead 25 can be suppressed in the electronic device A11, as compared to the case where the section boundary 25C is, for example, disposed at the boundary 2504 (see FIG. 15) between the extending portion 253 and the bent portion 255 or at the boundary 2505 (see FIG. 15) between the mounting portion 252 and the bent portion 255.

In the above first embodiment (and its variation), an example is shown where the first section boundary 21C overlaps with the boundary 2101 between the root portion 211 and the bent portion 214. As described above, the first section boundary 21C may need to be located between the boundary 2101 and the central boundary 2103. As another example, as shown in FIG. 16, the electronic device of the present disclosure may be configured such that the first section boundary 21C overlaps with the boundary 2102 between the extending portion 213 and the bent portion 214. Alternatively, as shown in FIG. 17, the electronic device of the present disclosure may be configured such that the first section boundary 21C overlaps with the central boundary 2103 of the extending portion 213, for example. Such a configuration is also applicable to each of the outer leads 22, 24 and 25.

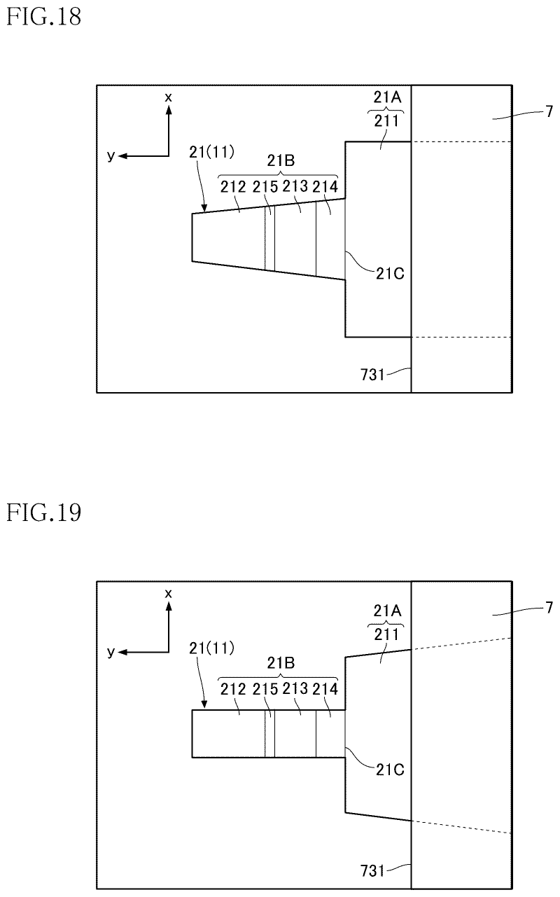

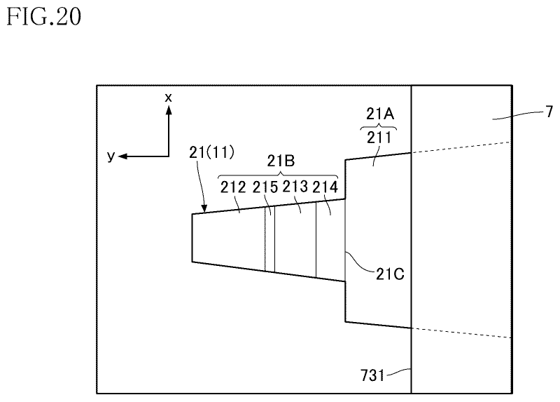

In the above first embodiment (including variations), the first section 21A and the second section 21B are each rectangular in plan view, but at least one of the first section 21A and the second section 21B may be tapered in plan view. For example, in the electronic device of the present disclosure, the second section 21B may have a shape tapering toward the tip of the mounting portion 212 (the far side end edge from the sealing resin 7), as shown in FIG. 18. Alternatively, in the electronic device of the present disclosure, the first section 21A may have a shape tapering toward the tip of the root portion 211 (the end edge on the side far from the sealing resin 7 and connected to the bent portion 214), as shown in FIG. 19. Alternatively, in the electronic device of the present disclosure, each of the first section 21A and the second section 21B may be tapered, as shown in FIG. 20. Unlike the examples shown in FIGS. 18 to 20, the end of the first section 21A connecting to the second section 21B and the end of the second section 21B connecting to the first section 21A may have the same width (second dimension in the second direction x). Such a configuration is also applicable to each outer lead 22, 24 and 25.

### Second Embodiment

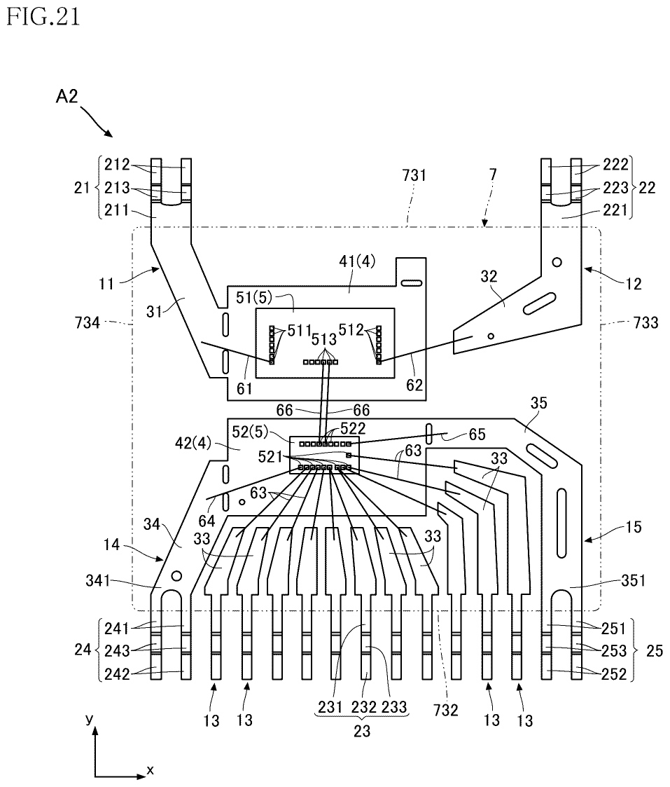

FIGS. 21 to 24 show an electronic device A2 according to a second embodiment. The electronic device A2 differs from the electronic device A1 in the following points. First, the outer lead 21 includes two second sections 21B. Second, the outer lead 22 includes two fourth sections 22B.

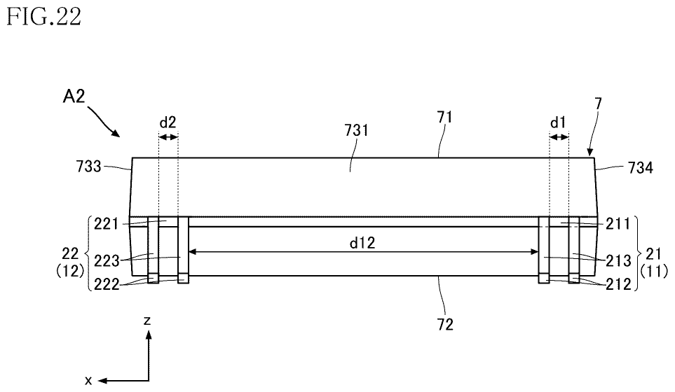

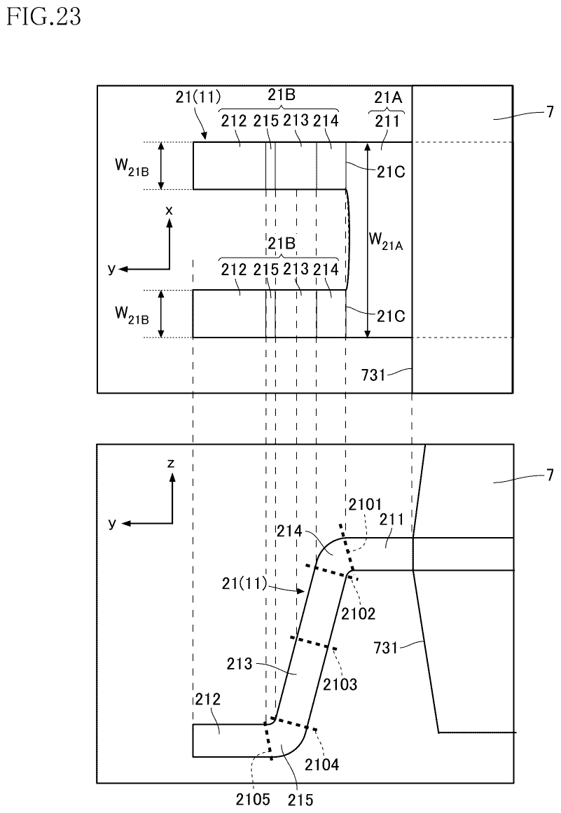

As shown in FIG. 23, in plan view, the outer lead 21 of the electronic device A2 includes the two second sections 21B extending from one first section 21A in the first direction y. The two second sections 21B are spaced apart from each other in the second direction x. Each first section boundary 21C between the two respective second sections 21B and the first section 21A is located between the boundary 2101, which is between the root portion 211 and the bent portion 214, and the central boundary 2103 of the extending portion 213, and in the illustrated example, overlaps with the boundary 2101. Each second section 21B includes the mounting portion 212, the extending portion 213, and the two bent portions 214 and 215. The spacing dl (see FIG. 22) along the second direction x between the two second sections 21B (the mounting portions 212) is, for example, equal to the spacing d3. In the illustrated example, the outer lead 21 includes the two second sections 21B, but may include three or more second sections 21B.

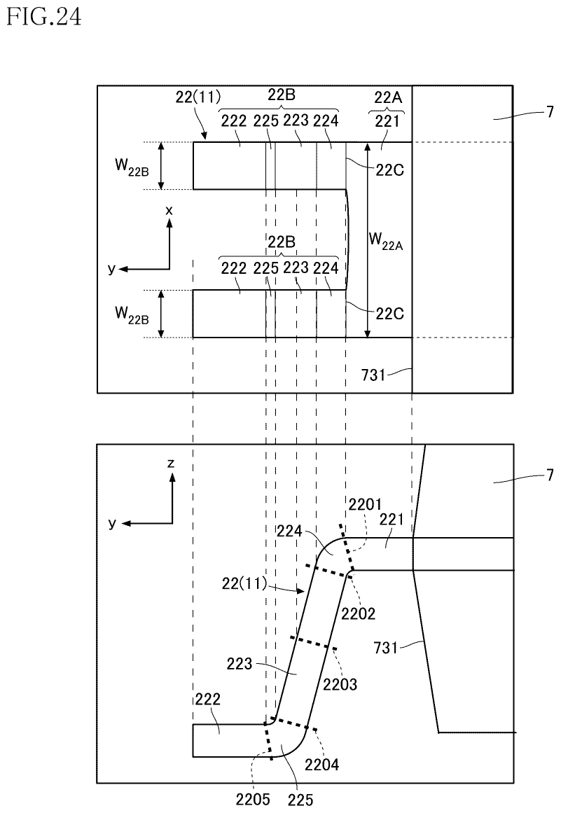

As shown in FIG. 24, in plan view, the outer lead 22 of the electronic device A2 includes the two fourth sections 22B extending from one third section 22A in the first direction y in plan view. The two fourth sections 22B are spaced apart from each other in the second direction x. Each second section boundary 22C between the two respective fourth sections 22B and the third section 22A is located between the boundary 2201, which is between the root portion 221 and the bent portion 224, and the central boundary 2203 of the extending portion 223, and in the illustrated example, overlaps with the boundary 2201. Each fourth section 22B includes the mounting portion 222, the extending portion 223, and the two bent portions 224 and 225. The spacing d2 (see FIG. 22) along the second direction x between the two fourth sections 22B (the mounting portions 222) is, for example, equal to the spacing d3. In the illustrated example, the outer lead 22 includes the two fourth sections 22B, but may include three or more fourth sections 22B.

The variation in the shape of outer lead 21 in the electronic device A2 can be suppressed, as with the electronic device A1. Further, the variation in the shape of outer lead 22 in the electronic device A2 can be suppressed, as with the electronic device A1. In addition, the electronic device A2 may have a configuration in common with the electronic device A1, thereby achieving the same effect as the electronic device A1.

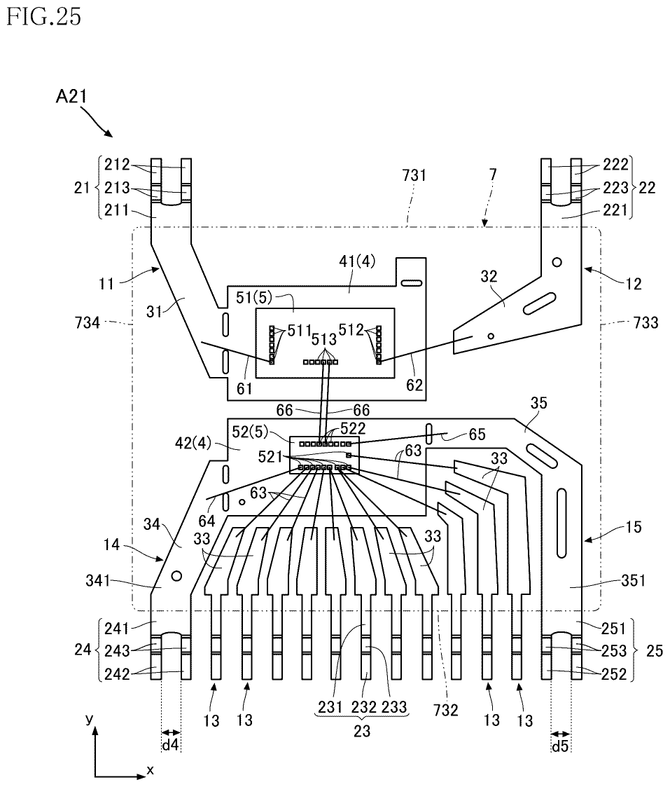

FIGS. 25 to 27 show an electronic device A21 according to a variation of the second embodiment. The electronic device A21 differs from the electronic device A2 in the following points. That is, in the electronic device A21, each outer lead 24 and 25 has the same shape as the outer lead 21 (the outer lead 22).

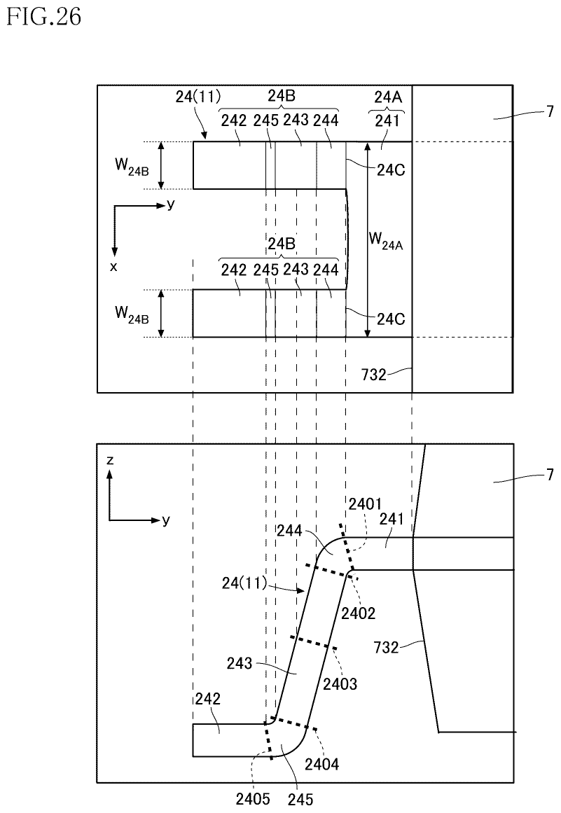

As shown in FIG. 26, in plan view, the outer lead 24 of the electronic device A21 includes the two sections 24B extending from one section 24A in the first direction y. The two sections 24B are spaced apart from each other in the second direction x. Each section boundary 24C between the section 24A and the two respective sections 24B is located between the boundary 2401, which is between the root portion 241 and the bent portion 244, and the central boundary 2403 of the extending portion 243, and in the illustrated example, overlaps with the boundary 2401. Each section 24B includes the mounting portion 242, the extending portion 243, and the two bent portions 244 and 245. The spacing d4 (see FIG. 25) along the second direction x between the two sections 24B (the mounting portions 242) is, for example, equal to the spacing d3. In the illustrated example, the outer lead 24 includes the two sections 24B, but may include three or more sections 24B.

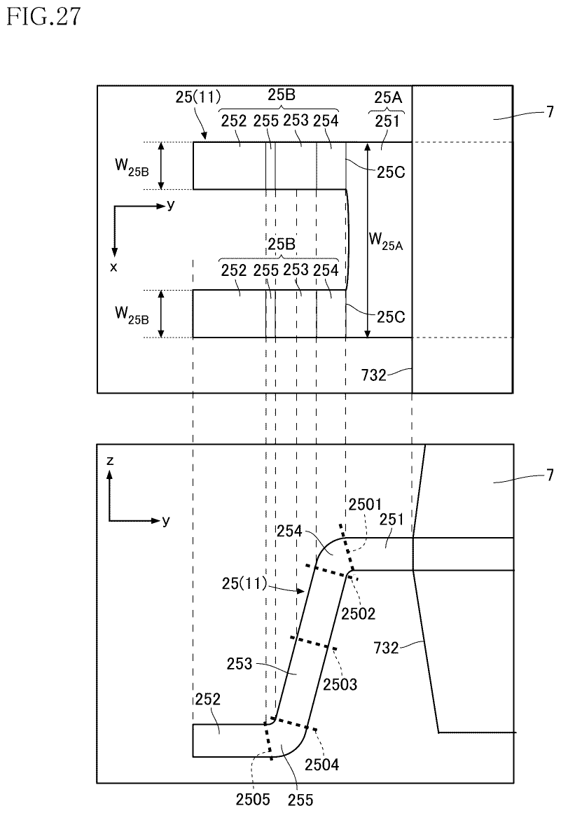

As shown in FIG. 27, in plan view, the outer lead 25 of the electronic device A21 includes the two sections 25B extending from one section 25A in the first direction y. The two sections 25B are spaced apart from each other in the second direction x. Each section boundary 25C between the section 25A and the two respective sections 25B is located between the boundary 2501, which is between the root portion 251 and the bent portion 254, and the central boundary 2503 of the extending portion 253, and in the illustrated example, overlaps with the boundary 2501. Each section 25B includes the mounting portion 252, the extending portion 253, and the two bent portions 254 and 255. The spacing d5 (see FIG. 25) along the second direction x between the two sections 25B (the mounting portions 252) is, for example, equal to the spacing d3. In the illustrated example, the outer lead 25 includes the two sections 25B, but may include three or more sections 25B.

The variation in the shape of each outer lead 21 and 22 in the electronic device A21 can be suppressed, as with the electronic device A2. In addition, the electronic device A21 may have a configuration in common with the electronic device A2, thereby achieving the same effect as the electronic device A2.

Further, in the electronic device A21, since each of the two outer leads 24 and 25 is configured in the same manner as the outer lead 21 (the outer lead 22), the variation in the shape of each outer lead 24 and 25 can be suppressed.

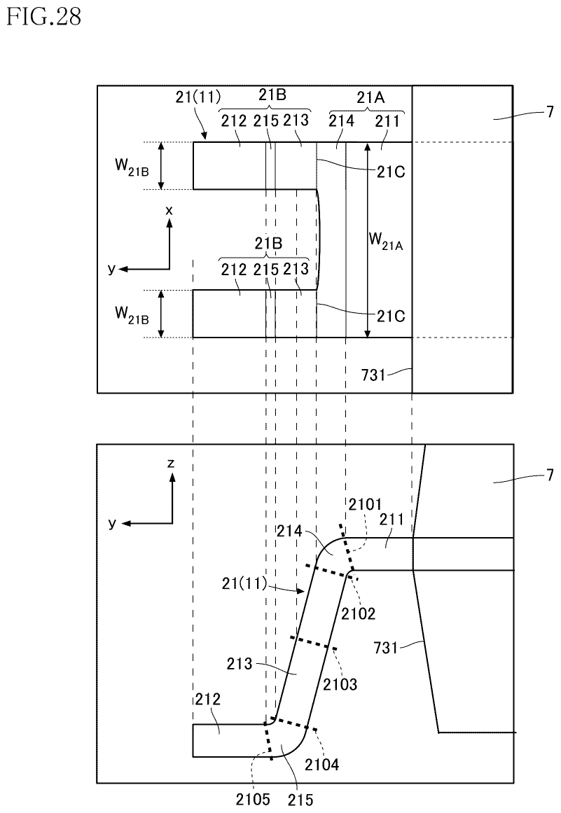

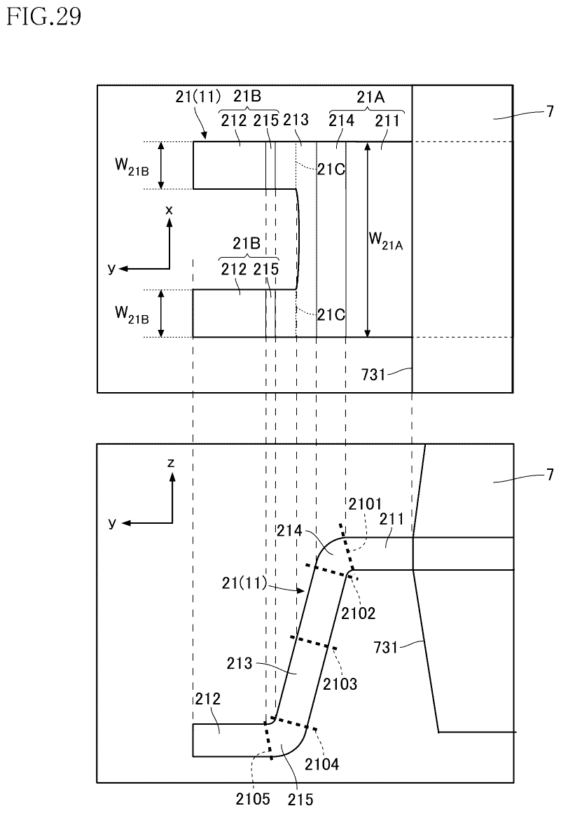

In the above first embodiment (and its variation), an example is shown where each first section boundary 21C overlaps with the boundary 2101 between the root portion 211 and the bent portion 214. As described above, the first section boundary 21C may need to be located between the boundary 2101 and the central boundary 2103. In a configuration different from the electronic device A2, as shown in FIG. 28, the first section boundary 21C may overlap with the boundary 2102 between the extending portion 213 and the bent portion 214, for example. Alternatively, in a configuration different from the electronic device A2, as shown in FIG. 29, the first section boundary 21C may be configured to overlap with the central boundary 2103 of the extending portion 213, for example. Such a configuration is also applicable to each of the outer leads 22, 24 and 25.

As understood from the above second embodiment (and its variation), in the electronic device of the present disclosure, the number of the second sections 21B, the fourth sections 22B, the sections 24B and the sections 25B is not limited to one and may be two or more.

### Third Embodiment

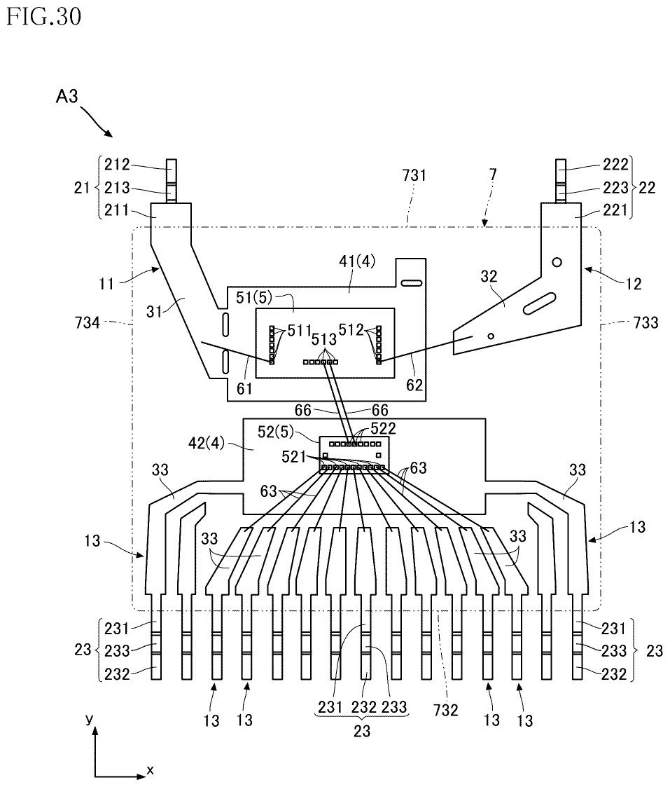

FIG. 30 shows an electronic device A3 according to a third embodiment. The electronic device A3 differs from the electronic device A1 in that it does not comprise the fourth lead 14 and the fifth lead 15.

The external appearance of the electronic device A3 is the same as that of the electronic device A1. However, in the electronic device A3, the third leads 13 includes one located at the outermost side in the second direction x and one located at the opposite outermost side in the second direction x, both of which are connected to the second pad 42.

The variation in the shape of each outer lead 21 and 22 in electronic device A3 can be suppressed, as with the electronic devices A1 and A2. In In addition, the electronic device A3 may have a configuration in common with the electronic devices A1 and A2, thereby achieving the same effect as each of the electronic devices A1 and A2.

### Fourth Embodiment

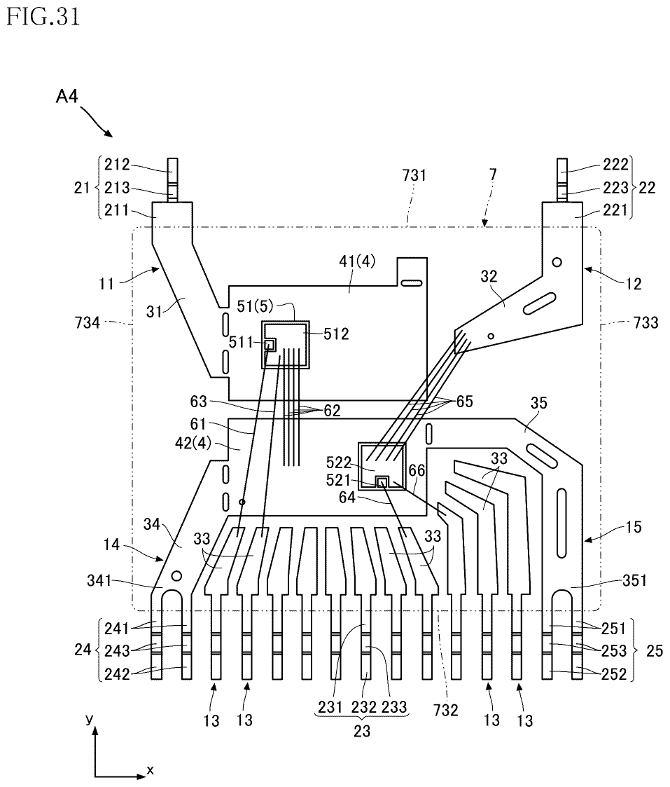

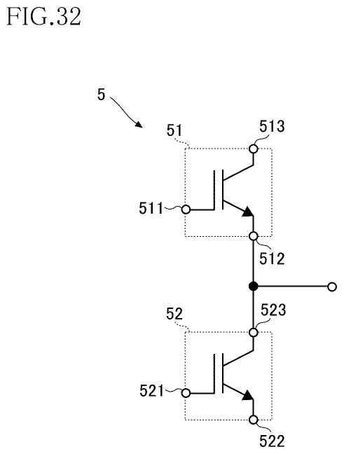

FIGS. 31 and 32 show an electronic device A4 according to a fourth embodiment. The electronic device A4 differs from the electronic device A1 in the function of the electronic component 5.

The electronic component 5 of the electronic device A4 has a power conversion function rather than a voltage detection function. The first chip 51 and the second chip 52 are switching elements, respectively. In the circuit diagram of FIG. 32, each of the first chip 51 and the second chip 52 is shown as an example of an IGBT (Insulated Gate Bipolar Transistor), but may be another type of transistor, such as a MOSFET (Metal-Oxide-Semiconductor Field Effect Transistor) or a bipolar transistor rather than an IGBT.

As shown in FIG. 32, the first chip 51 includes three electrodes 511, 512 and 513. In the example where the first chip 51 is an IGBT, the electrode 511 is the gate, the electrode 512 is the emitter, and the electrode 513 is the collector. The first chip 51 is configured, for example, in a vertical structure, with the two electrodes 511 and 512 disposed on the top surface (the surface facing upward in the thickness direction z) and the electrode 513 on the bottom surface (the surface facing downward in the thickness direction z). The first chip 51 is bonded to the first pad 41 through a conductive bonding material such as solder, electrically connecting the electrode 513 on the bottom surface to the first pad 41.

As shown in FIG. 32, the second chip 52 includes three electrodes 521, 522 and 523. In the example where the second chip 52 is an IGBT, the electrode 521 is the gate, the electrode 522 is the emitter, and the electrode 523 is the collector. The second chip 52 is configured, for example, in a vertical structure, with the two electrodes 521 and 522 disposed on the top surface (the surface facing upward in the thickness direction z) and the electrode 523 on the bottom surface (the surface facing downward in the thickness direction z). The second chip 52 is bonded to the second pad 42 through a conductive bonding material such as solder, electrically connecting the electrode 523 on the bottom surface to the second pad 42.

The first chip 51 and the second chip 52 may have a horizontal structure rather than the vertical structure. In this case, the electrode 513 is disposed on the top surface of the first chip 51, and the electrode 523 is disposed on the top surface of second chip 52. Thus, the electrode 513 and the first pad 41 (or optionally the inner lead 31) may be electrically connected to each other through a bonding wire or a metal plate, and the electrode 523 and the second pad 42 (or optionally the inner lead 34 or the inner lead 35) may be electrically connected to each other through a bonding wire or a metal plate.

In the electronic device A4, the connection member 61 is bonded to the electrode 511 and the inner lead 33 of one of the third leads 13, thereby electrically connecting them. The mounting portion 232 of the third lead 13 to which the connection member 61 is bonded serves as a signal input terminal for receiving a drive signal of the first chip 51. The connection members 62 are bonded to the electrode 512 and the second pad 42, thereby electrically connecting them. The connection member 63 is bonded to the electrode 512 and the inner lead 33 of one of the third leads 13, thereby electrically connecting them. The mounting portion 232 of the third lead 13 to which the connection member 63 is bonded serves as a detection terminal for detecting a current flowing through the first chip 51. The connection member 64 is bonded to the electrode 521 and the inner lead 33 of one of the third leads 13, thereby electrically connecting them. The mounting portion 232 of the third lead 13 to which the connection member 64 is bonded serves as a signal input terminal for receiving a drive signal of the second chip 52. The connection members 65 are bonded to the electrode 522 and the inner lead 32 of the second lead 12, thereby electrically connecting them. The connection member 66 is bonded to the electrode 522 and the inner lead 33 of one of the third leads 13, thereby electrically connecting them. The mounting portion 232 of the third lead 13 to which the connection member 66 is bonded serves as a detection terminal for detecting a current flowing through the second chip 52.

The electronic device A4 receives a power supply voltage (e.g., DC voltage) at the outer lead 21 and the outer lead 22, and converts it to a predetermined voltage (e.g., AC voltage) through the respective switching operations of the first chip 51 and the second chip 52. This converted voltage is output from the two outer leads 24 and 25.

The variation in the shape of each of the outer leads 21 and 22 in the electronic device A4 can be suppressed, as with the electronic devices A1 to A3. In addition, the electronic device A4 may have a configuration in common with the electronic devices A1 to A3, thereby achieving the same effect as each of the electronic devices A1 to A3.

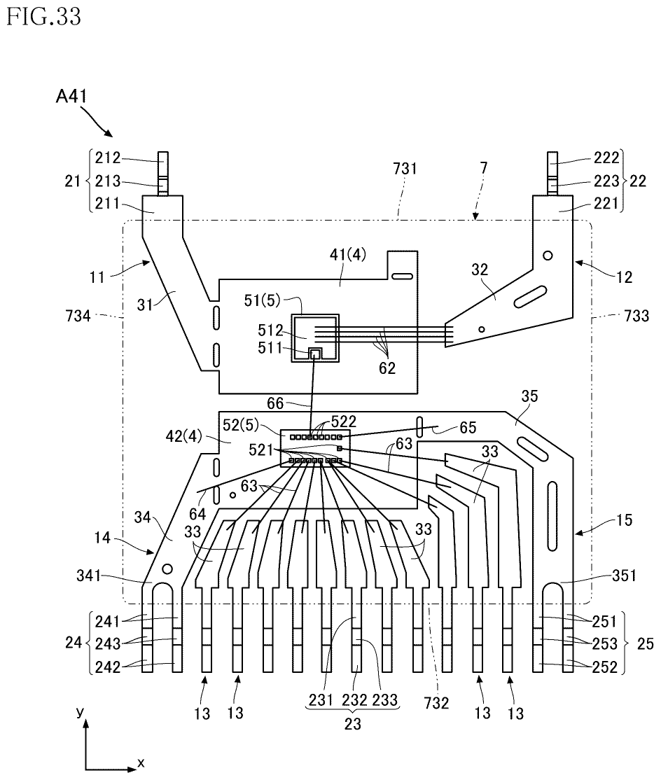

FIG. 33 shows an electronic device A41 according to a variation of the fourth embodiment. The second chip 52 of the electronic device A41 is not a switching element but a control IC to control the drive of the first chip 51. Such a variation also achieves the same effect as the electronic device A4.

As understood from the above fourth embodiment and its variation, the function of the electronic component 5 is not limited to the voltage detection function in the electronic devices of the present disclosure. In the electronic device of the present disclosure, the electronic component 5 (the first chip 51 and the second chip 52) includes a semiconductor element made of semiconductor material.

### Fifth Embodiment

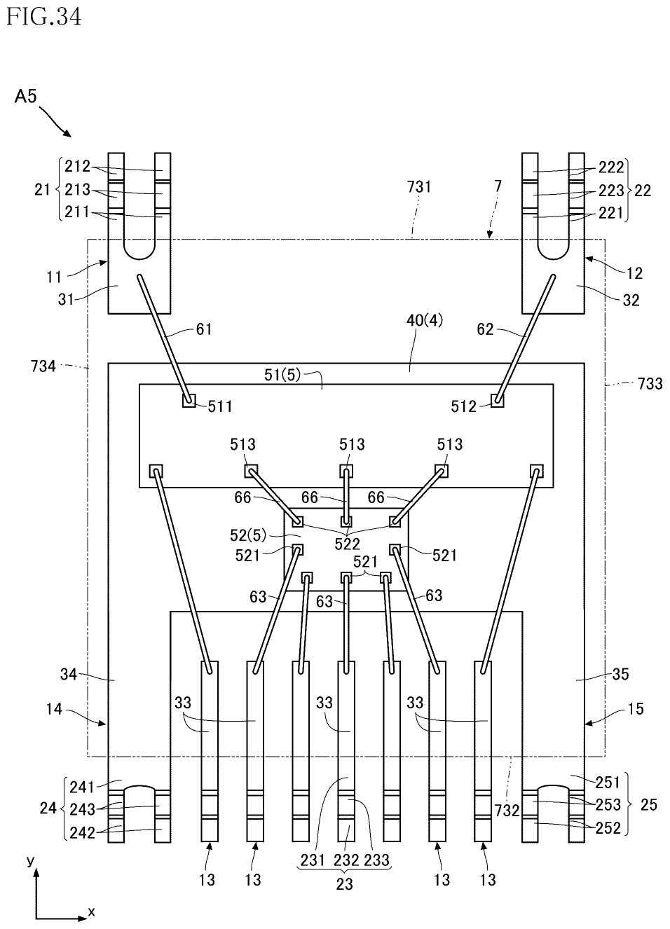

FIG. 34 shows an electronic device A 5 according to a fifth embodiment. As understood from FIG. 34, the electronic device A5 differs from the electronic device A1 in that the first chip 51 and the second chip 52 are mounted on a single pad (a pad 40 described below).

In the electronic device A5, the die pad 4 includes one pad 40. The first chip 51 and the second chip 52 are mounted on the pad 40. In the illustrated example, the pad 40 (the die pad 4) is spaced apart from the first lead 11, the second lead 12 and the third leads 13, and is connected to the fourth lead 14 and the fifth lead 15.

In the electronic device A5, the outer lead 21 includes parts separated from each other, each of which includes the root portion 211, the mounting portion 212, the extending portion 213, and the two bent portions 214 and 215. However, in the electronic device A5, each separated part of the outer lead 21 has the same respective widths (dimensions in the second direction x) as the root portion 211, the mounting portion 212, the extending portion 213, and the two bent portions 214 and 215. Similarly, in the electronic device A5, the outer lead 22 includes parts separated from each other, each of which includes the root portion 221, the mounting portion 222, the extending portion 223, and the two bent portions 224 and 225. However, in the electronic device A5, each separated part of the outer lead 22 has the same respective widths (dimensions in the second direction x) of the root portion 221, the mounting portion 222, the extending portion 223, and the two bent portions 224 and 225.

In the electronic device A5, the variation in the shape of each outer lead 24 and 25 can be suppressed, as with the electronic devices A11 and A21.

In addition, the electronic device A5 may have a configuration in common with the electronic devices A1 to A4, A11, A21, and A41, thereby achieving the same effect as each of the electronic devices A1 to A4, A11, A21, and A41.

As understood from the above fifth embodiment, in the electronic device of the present disclosure, the die pad 4 is not limited to the configuration including the first pad 41 and the second pad 42. In other words, in the electronic device of the present disclosure, whether or not the die pad 4 is divided into a plurality of pads is not particularly limited.

### Sixth Embodiment

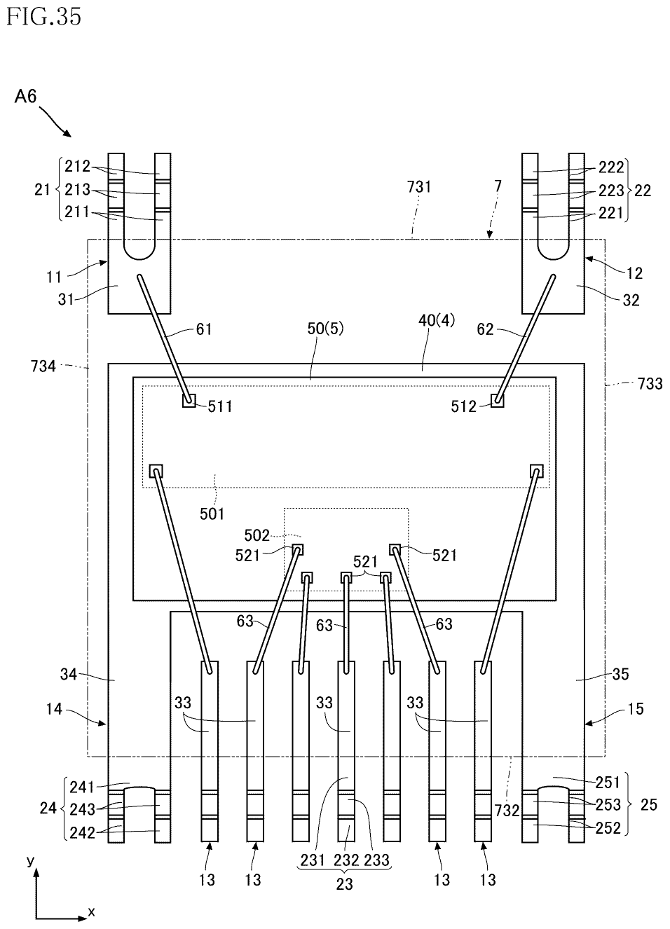

FIG. 35 shows an electronic device A6 according to a sixth embodiment. The electronic device A6 differs from the electronic device A5 in that the electronic component 5 is formed in a single chip 50.

The chip 50 may include a first functional portion 501 and a second functional portion 502. The chip 50 integrates the first functional portion 501 and the second functional portion 502 into a single chip. The respective functions of the first functional portion 501 and the second functional portion 502 are not particularly limited. For example, the first functional portion 501 functions as sending a signal according to the potential of the outer lead 21 and a signal according to the potential of the outer lead 22, as with the first chip 51 of the electronic device A1, and the second functional portion 502 functions as sending a signal according to the potential difference between the two outer leads 21 and 22, as with the second chip 52 of the electronic device A1. Unlike this configuration, the first functional portion 501 may have a switching function as with the first chip 51 of the electronic device A3, and the second functional portion 502 may have a switching function as with the second chip 52 of the electronic device A3. The first functional portion 501 and the second functional portion 502 are conducted, for example, by internal wiring (not shown) of the chip 50.

The variation in the shape of each outer lead 24 and 25 in the electronic device A6 can be suppressed, as with electronic device A5. In addition, the electronic device A6 may have a configuration in common with the electronic devices A1 to A5, A11, A21, and A41, thereby achieving the same effect as each of the electronic devices A1 to A5, A11, A21, and A41.

As understood from the above sixth embodiment, in the electronic device of the present disclosure, the electronic component 5 is not limited to a configuration including the first chip 51 and the second chip 52. In other words, in the electronic device of the present disclosure, whether or not the electronic component 5 is configured to include a plurality of chips is not particularly limited.

In the above first to sixth embodiments (and their variations), two or more of the outer leads 21, 22, 24 and 25 include two sections (the first section 21A and the second section 21B, the third section 22A and the fourth section 22B, the section 24A and the section 24B, or the section 25A and the section 25B) with different widths from each other. Unlike this example, only one of the outer leads 21, 22, 24 and 25 may be configured to include two sections with different widths from each other. For example, one of the outer leads 21, 22, 24 and 25 that exhibits the greatest variation in shape may be configured to include two sections with different widths.

The electronic devices according to the present disclosure are not limited to the embodiments described above. The specific configuration of each part of the electronic device of the present disclosure may suitably be designed and changed in various manners. For example, the present disclosure includes the embodiments described in the following clauses.

### Clause 1

An electronic device comprising:
an electronic component;
a sealing resin including a first resin side surface facing one side of a first direction orthogonal to a thickness direction and covering the electronic component; and
an outer lead including a root portion extending from the first resin side surface in the first direction, a mounting portion offset on one side of the thickness direction with respect to the root portion, and an extending portion connected to the root portion through a first bent portion and connected to the mounting portion through a second bent portion,
wherein the outer lead includes a first section including the root portion, and a second section including the mounting portion and connected to the first section,
a dimension of the first section in a second direction orthogonal to the thickness direction and the first direction is greater than a dimension of the second section in the second direction, and
a first section boundary between the first section and the second section is located between a first boundary, which is between the root portion and the first bent portion, and a center of the extending portion in an extending direction from the first bent portion to the second bent portion.

### Clause 2

The electronic device according to clause 1, wherein the first section boundary is located between the first boundary and a second boundary, which is between the first bent portion and the extending portion.

### Clause 3

The electronic device according to clause 2, wherein the first section boundary overlaps with the first boundary.

### Clause 4

The electronic device according to any one of clauses 1 to 3, wherein the extending portion is inclined with respect to the thickness direction as viewed in the second direction.

### Clause 5

The electronic device according to any one of clauses 1 to 4, wherein the outer lead includes an additional second section, the two second sections are spaced apart in the second direction.

### Clause 6

The electronic device according to any one of clauses 1 to 5, further comprising a second outer lead, in addition to a first outer lead corresponding to the outer lead,
wherein the second outer lead is disposed on one side of the second direction with respect to the first outer lead and projects from the first resin side surface.

### Clause 7

The electronic device according to clause 6, wherein an entirety of the second outer lead overlaps with an entirety of the first outer lead as viewed in the second direction.

### Clause 8

The electronic device according to clause 7, wherein the second outer lead includes a third section extending from the first resin side surface in the first direction and a fourth section connected to the third section,
a dimension of the third section in the second direction is greater than a dimension of the fourth section in the second direction,
a second section boundary between the third section and the fourth section overlaps with the first section boundary as viewed in the first direction.

### Clause 9

The electronic device according to any one of clauses 6 to 8, further comprising a plurality of third outer leads, wherein the sealing resin includes a second resin side surface facing a side opposite to the first resin side surface in the first direction, and each of the plurality of third outer leads projects from the second resin side surface.

### Clause 10

The electronic device according to clause 9, wherein the plurality of third outer leads are disposed at equal intervals along the second direction, and
a spacing along the second direction between the first outer lead and the second outer lead is greater than a spacing along the second direction of the plurality of third outer leads.

### Clause 11

The electronic device according to clause 9 or 10, wherein each of the plurality of third outer leads has a uniform width in the second direction from a base close to the sealing resin in the first direction to a tip far from the sealing resin in the first direction.

### Clause 12

The electronic device according to clause 11, wherein each of the plurality of third outer leads includes a dimension in the second direction that is equal to the dimension of the second section in the second direction.

### Clause 13

The electronic device according to any one of clauses 6 to 12, wherein each of the first outer lead and the second outer lead is electrically connected to the electronic component.

### Clause 14

The electronic device according to clause 13, further comprising a die pad covered by the sealing resin,
wherein the electronic component is mounted on the die pad.

### Clause 15

The electronic device according to clause 14, further comprising a first inner lead covered by the sealing resin and extending from the first outer lead,
wherein the die pad includes a first pad connected to the first inner lead, and
the electronic component includes a first chip mounted on the first pad.

### Clause 16

The electronic device according to clause 15, further comprising a second inner lead covered by the sealing resin and extending from the second outer lead,
wherein the second inner lead is electrically connected to the first chip via a wire.

### Clause 18

The electronic device according to clause 15 or 16, wherein the die pad includes a second pad spaced from the first pad, and the electronic component includes a second chip mounted on the second pad.

The electronic device according to any one of clauses 1 to 17, wherein the sealing resin includes a resin reverse surface facing the one side of the thickness direction, and
the mounting portion overlaps with the resin reverse surface as viewed in the first direction.

### REFERENCE NUMERALS

A1, A11, A2, A21, A , A4, A41, A5, A6: Electronic device
11: First lead 12: Second lead 13: Third lead 14: Fourth lead
15: Fifth lead 21: Outer lead 211: Root portion
212: The mounting portion 213: Extending portion 214, 215: Bent portion
21A: First section 21B: Second section 21C: First section boundary
2101, 2102, 2104, 2105: Boundary 2103: Central boundary
22: Outer lead 221: Root portion 222: The mounting portion
223: Extending portion 224, 225: Bent portion
22A: Third section 22B: Fourth section 22C: Second section boundary
2201, 2202, 2204, 2205: Boundary 2203: Central boundary
23: Outer lead 231: Root portion 232: The mounting portion
233: Extending portion 234, 235: Bent portion
24: Outer lead 241: Root portion 242: The mounting portion
243: Extending portion 244, 245: Bent portion
2401, 2402, 2404, 2405: Boundary 2403: Central boundary
24A: Section 24B: Section 24C: Section boundary
25: Outer lead 251: Root portion 252: The mounting portion
253: Extending portion 254, 255: Bent portion
2501, 2502, 2504, 2505: Boundary 2503: Central boundary
25A: Section 25B: Section 25C: Section boundary
31 to 35: Inner lead 341, 351: Branched portion
4: Die pad 40: Pad 41: First pad 42: Second pad
5: Electronic component 50: Chip 501: First functional portion
502: Second functional portion 51: First Chip 511 to 513: Electrode
52: Second chip 521 to 523: Electrode
61 to 66: Connection members 7: Sealing resin
71: Resin obverse surface 72: Resin reverse surface
731 to 734: Resin side surface 9: Lead frame 91: Tie bar
C1, C2: Connection point GND: Ground OP: Operational amplifier
R1 to R5: Resistor element T1, T2: Terminal

1. An electronic device comprising:
an electronic component;
a sealing resin including a first resin side surface facing one side of a first direction orthogonal to a thickness direction and covering the electronic component; and
an outer lead including a root portion extending from the first resin side surface in the first direction, a mounting portion offset on one side of the thickness direction with respect to the root portion, and an extending portion connected to the root portion through a first bent portion and connected to the mounting portion through a second bent portion,
wherein the outer lead includes a first section including the root portion, and a second section including the mounting portion and connected to the first section,
a dimension of the first section in a second direction orthogonal to the thickness direction and the first direction is greater than a dimension of the second section in the second direction, and
a first section boundary between the first section and the second section is located between a first boundary, which is between the root portion and the first bent portion, and a center of the extending portion in an extending direction from the first bent portion to the second bent portion.

2. The electronic device according to claim 1, wherein the first section boundary is located between the first boundary and a second boundary, which is between the first bent portion and the extending portion.

3. The electronic device according to claim 2, wherein the first section boundary overlaps with the first boundary.

4. The electronic device according to claim 1, wherein the extending portion is inclined with respect to the thickness direction as viewed in the second direction.

5. The electronic device according to claim 1, wherein the outer lead includes an additional second section,
the two second sections are spaced apart in the second direction.

6. The electronic device according to claim 1, further comprising a second outer lead, in addition to a first outer lead corresponding to the outer lead,
wherein the second outer lead is disposed on one side of the second direction with respect to the first outer lead and projects from the first resin side surface.

7. The electronic device according to claim 6, wherein an entirety of the second outer lead overlaps with an entirety of the first outer lead as viewed in the second direction.

8. The electronic device according to claim 7, wherein the second outer lead includes a third section extending from the first resin side surface in the first direction and a fourth section connected to the third section,
a dimension of the third section in the second direction is greater than a dimension of the fourth section in the second direction,
a second section boundary between the third section and the fourth section overlaps with the first section boundary as viewed in the first direction.

9. The electronic device according to claim 6, further comprising a plurality of third outer leads,
wherein the sealing resin includes a second resin side surface facing a side opposite to the first resin side surface in the first direction, and
each of the plurality of third outer leads projects from the second resin side surface.

10. The electronic device according to claim 9, wherein the plurality of third outer leads are disposed at equal intervals along the second direction, and
a spacing along the second direction between the first outer lead and the second outer lead is greater than a spacing along the second direction of the plurality of third outer leads.

11. The electronic device according to claim 9, wherein each of the plurality of third outer leads has a uniform width in the second direction from a base close to the sealing resin in the first direction to a tip far from the sealing resin in the first direction.

12. The electronic device according to claim 11, wherein each of the plurality of third outer leads includes a dimension in the second direction that is equal to the dimension of the second section in the second direction.

13. The electronic device according to claim 6, wherein each of the first outer lead and the second outer lead is electrically connected to the electronic component.

14. The electronic device according to claim 13, further comprising a die pad covered by the sealing resin,
wherein the electronic component is mounted on the die pad.

15. The electronic device according to claim 14, further comprising a first inner lead covered by the sealing resin and extending from the first outer lead,
wherein the die pad includes a first pad connected to the first inner lead, and
the electronic component includes a first chip mounted on the first pad.

16. The electronic device according to claim 15, further comprising a second inner lead covered by the sealing resin and extending from the second outer lead,
wherein the second inner lead is electrically connected to the first chip via a wire.

17. The electronic device according to claim 15, wherein the die pad includes a second pad spaced from the first pad, and
the electronic component includes a second chip mounted on the second pad.

18. The electronic device according to claim 1, wherein the sealing resin includes a resin reverse surface facing the one side of the thickness direction, and
the mounting portion overlaps with the resin reverse surface as viewed in the first direction.
